(19) United States
(12) Patent Application Publication
(10) Pub. No.: US 2025/0167160 A1
(43) Pub. Date: May 22, 2025

(54) ADHESIVE STRUCTURE AND MANUFACTURING METHOD THEREOF, ELECTRONIC COMPONENT AND MANUFACTURING METHOD THEREOF, AND ADHESIVE LAYER FOR TRANSFER

(71) Applicants: Tohru YASHIRO, Kanagawa (JP); Fuminari KANEKO, Kanagawa (JP); Yuto MATSUOKA, Tokyo (JP); Takeshi ENDOH, Kanagawa (JP); Shinichi HATANAKA, Tokyo (JP); Shinji MATSUMOTO, Kanagawa (JP); Muneaki IWATA, Kanagawa (JP); Ryuya MASHIKO, Tokyo (JP); Hiroyuki TAKAHASHI, Kanagawa (JP); Hiroshi KONDO, Kanagawa (JP); Yuko KOMAI, Kanagawa (JP); Hiroyuki HIRATSUKA, Kanagawa (JP)

(72) Inventors: Tohru YASHIRO, Kanagawa (JP); Fuminari KANEKO, Kanagawa (JP); Yuto MATSUOKA, Tokyo (JP); Takeshi ENDOH, Kanagawa (JP); Shinichi HATANAKA, Tokyo (JP); Shinji MATSUMOTO, Kanagawa (JP); Muneaki IWATA, Kanagawa (JP); Ryuya MASHIKO, Tokyo (JP); Hiroyuki TAKAHASHI, Kanagawa (JP); Hiroshi KONDO, Kanagawa (JP); Yuko KOMAI, Kanagawa (JP); Hiroyuki HIRATSUKA, Kanagawa (JP)

(21) Appl. No.: 18/836,785

(22) PCT Filed: Mar. 13, 2023
(86) PCT No.: PCT/IB2023/052374

§ 371 Date: Aug. 8, 2024

(30) Foreign Application Priority Data
Mar. 22, 2022 (JP) 2022-044905
Nov. 29, 2022 (JP) 2022-190614

(51) Int. Cl. H01L 23/00; C09J 5/00; C09J 9/00

(52) U.S. Cl. CPC H01L 24/29; C09J 5/00; C09J 9/00; H01L 24/32; C09J 2203/326; C09J 2301/204; C09J 2301/206; C09J 2301/314; C09J 2301/502; H01L 2224/29076; H01L 2224/32225

(57) ABSTRACT

An adhesive structure includes: an adhesive portion to adhere to a contact object; and a low elastic portion having an elastic modulus lower than an elastic modulus of the adhesive portion. At least one of the adhesive portion and the low elastic portion has a patterned shape.

### TECHNICAL FIELD

The present disclosure relates to an adhesive structure and a manufacturing method thereof, an electronic component and a manufacturing method thereof, and an adhesive layer for transfer.

### BACKGROUND ART

As electronic circuit boards are more highly integrated and operate at higher speeds, the electronic circuit boards are subject to an increase in temperature rise due to heat-generating components such as integrated circuit (IC) chips, and there is a demand for reliability of heat resistance in adhesion and connection of mounted circuits. One factor that reduces the reliability of adhesion and connection is thermal stress caused by the difference in linear thermal expansion coefficient between a semiconductor (die) and various materials adhered to the semiconductor (die). Specifically, the linear thermal expansion coefficient of a semiconductor (die) is about 3 ppm/K, while the linear thermal expansion coefficient of a mounting board is as high as 15 ppm/K or more. This causes thermal stress in heating manufacturing process steps such as reflow and in a heat cycle such as heat generated by driving, making it easy to cause poor adhesion of the semiconductor (die) and poor connection.

Conventionally, solution-based die bonding pastes and sheet-like die attach films have been used as die bonding members for adhering dies and for adhering a die to a substrate.

For die attach films, there is a proposal to improve the reliability of heat resistance in a manner that an epoxy resin, a curing agent, and a polymer compound that is incompatible with the epoxy resin are used to form a phase-separated sea-island structure between an adhesive portion made of the epoxy resin and the polymer compound with stress relaxation properties by curing (see PTL 1). An adhesive layer (ACRYSET BP, from Nippon Shokubai Co., Ltd.) has also been proposed in which an elastic rubber (low elastic portion) is mixed with an epoxy resin (adhesive portion). There is known a die-bonding member imparted with thermal conductivity as a heat-dissipating function in addition to the adhesive function.

### CITATION LIST

### Patent Literature

[PTL 1]
Japanese Unexamined Patent Application Publication No. 2011-084743

### SUMMARY OF INVENTION

### Technical Problem

An object of the present invention is to provide an adhesive structure that is excellent in adhesiveness, heat resistance, and stress relaxation properties and that can be made a thin film.

### Solution to Problem

An adhesive structure of the present embodiment as a solution to the above-mentioned problems includes: an adhesive portion to adhere to a contact object; and a low elastic portion having an elastic modulus lower than an elastic modulus of the adhesive portion, at least one of the adhesive portion and the low elastic portion having a patterned shape.

### Advantageous Effects of Invention

According to the present embodiment, it is possible to provide an adhesive structure that is excellent in adhesiveness, heat resistance, and stress relaxation properties and that can be made a thin film.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings.

FIG. 1A is a schematic cross-sectional view in a thickness direction, of an adhesive structure according to an embodiment of the present invention.

FIG. 1B is a schematic cross-sectional view in a plane direction, of the adhesive structure in FIG. 1A.

FIG. 2A is a schematic cross-sectional view in a thickness direction, of a conventional adhesive layer with stress relaxation properties.

FIG. 2B is a schematic cross-sectional view in a plane direction, of the conventional adhesive layer with stress relaxation properties in FIG. 2A.

FIG. 3A is a schematic cross-sectional view in a thickness direction, of an adhesive structure according to an embodiment of the present invention.

FIG. 3B is a schematic cross-sectional view in a thickness direction, of an adhesive structure according to an embodiment of the present invention.

FIG. 3C is a schematic cross-sectional view in a thickness direction, of an adhesive structure according to an embodiment of the present invention.

FIG. 3D is a schematic cross-sectional view in a thickness direction, of an adhesive structure according to an embodiment of the present invention.

FIG. 3E is a schematic cross-sectional view in a thickness direction, of an adhesive structure according to an embodiment of the present invention.

FIG. 3F is a schematic cross-sectional view in a thickness direction, of an adhesive structure according to an embodiment of the present invention.

FIG. 3G is a schematic cross-sectional view in a thickness direction, of an adhesive structure according to an embodiment of the present invention.

FIG. 3H is a schematic cross-sectional view in a thickness direction, of an adhesive structure according to an embodiment of the present invention.

FIG. 3I is a schematic cross-sectional view in a thickness direction, of an adhesive structure according to an embodiment of the present invention.

FIG. 4A is a schematic top view in a plane direction, of an adhesive structure according to an embodiment of the present invention.

FIG. 4B is a schematic top view in a plane direction, of an adhesive structure according to an embodiment of the present invention.

FIG. 4C is a schematic top view in a plane direction, of an adhesive structure according to an embodiment of the present invention.

FIG. 4D is a schematic top view in a plane direction, of an adhesive structure according to an embodiment of the present invention.

FIG. 4E is a schematic top view in a plane direction, of an adhesive structure according to an embodiment of the present invention.

FIG. 4F is a schematic top view in a plane direction, of an adhesive structure according to an embodiment of the present invention.

FIG. 4G is a schematic top view in a plane direction, of an adhesive structure according to an embodiment of the present invention.

FIG. 4H is a schematic top view in a plane direction, of an adhesive structure according to an embodiment of the present invention.

FIG. 5 is a schematic cross-sectional view of an electronic component using an adhesive structure according to an embodiment of the present invention.

FIG. 6 is a schematic cross-sectional view of an electronic component using an adhesive structure according to an embodiment of the present invention.

FIG. 7A is a schematic cross-sectional view of an electronic component using an adhesive structure according to an embodiment of the present invention.

FIG. 7B is a schematic cross-sectional view of an electronic component using an adhesive structure according to an embodiment of the present invention.

FIG. 8A is a schematic cross-sectional view of an electronic component using an adhesive structure according to an embodiment of the present invention.

FIG. 8B is a schematic cross-sectional view of an electronic component using an adhesive structure according to an embodiment of the present invention.

FIG. 9A is a schematic cross-sectional view of an electronic component using an adhesive structure according to an embodiment of the present invention.

FIG. 9B is a schematic cross-sectional view of an electronic component using an adhesive structure according to an embodiment of the present invention.

FIG. 10 is a schematic cross-sectional view of an electronic component using an adhesive structure according to an embodiment of the present invention.

FIG. 11A is a schematic cross-sectional view of a configuration in which an adhesive structure of Example 1 is used.

FIG. 11B is a schematic top view of the configuration in which the adhesive structure of Example 1 is used.

FIG. 12A is a schematic cross-sectional view of a configuration in which an adhesive structure of Example 5 is used.

FIG. 12B is a schematic top view of the configuration in which the adhesive structure of Example 5 is used.

FIG. 13 is a scanning electron microscope (SEM) photograph of a thermally conductive portion of Test Example 1.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

### (Adhesive Structure and Method for Manufacturing Adhesive Structure)

An adhesive structure of the present embodiment includes: an adhesive portion to adhere to a contact object; and a low elastic portion having an elastic modulus lower than an elastic modulus of the adhesive portion, at least one of the adhesive portion and the low elastic portion having a patterned shape, may optionally include a thermally conductive portion, and further optionally includes other members. The adhesive structure of the present embodiment is suitably manufactured by a method for manufacturing an adhesive structure of the present embodiment.

A method for manufacturing an adhesive structure of the present embodiment includes: discharging an adhesive portion forming ink for forming an adhesive portion to adhere to a contact object, from a nozzle, to pattern the adhesive portion; and discharging a low elastic portion forming ink for forming a low elastic portion having an elastic modulus lower than an elastic modulus of the adhesive portion, from a nozzle, to pattern the low elastic portion, may optionally include discharging a thermally conductive portion forming ink for forming a thermally conductive portion, from a nozzle, to form the thermally conductive portion continuous in a thickness direction of the adhesive structure, and further optionally includes other steps. The patterning may be performed in at least one of the discharging of the adhesive portion forming ink and the discharging of the low elastic portion forming ink.

Japanese Unexamined Patent Application Publication No. 2011-084743 proposes a technology that both to reduce the elastic modulus at room temperature to relax stress (specifically, to prevent cracks from being generated during reflow and prevent breaking in temperature cycle tests) and to increase the peel strength at high temperatures and the elastic modulus at high temperatures to have heat resistance and moisture resistance, improves the reliability of heat resistance in a manner that an epoxy resin, a curing agent, and a polymer compound that is incompatible with the epoxy resin are used to form a phase-separated sea-island structure between an adhesive portion made of the epoxy resin and the polymer compound with stress relaxation properties by curing.

However, in this proposed technology, since the adhesive material and the low elastic material are mixed in the adhesive layer and blended almost uniformly, there is a problem that the blending cannot be adjusted in the thickness direction of the adhesive layer (inside the film) and in the plane direction (the direction substantially perpendicular to the thickness direction) so that both the adhesiveness and stress relaxation are achieved.

In addition, there is a problem that it is difficult for the conventional die bonding members to deal with an increase in heat generated by the semiconductor and a reduction in the thickness of the semiconductor package. Specifically, an increase in heat generated by highly integrated dies and a reduction in the thickness of devices such as smartphones lead to a demand for die bonding members with increased heat resistance and a reduced film thickness. Such a reduced film thickness makes it likely for the stress relaxation performance to be reduced, and for the adhesive to peel off from the outer circumferential portion due to warpage. In addition, there is a problem that the adhesive layer is insufficiently filled in the lead wire portion for wire bonding, flip chip, and the like, so that bubbles and voids are likely to occur, resulting in a decrease in adhesive strength.

A sheet-shaped adhesive layer (for example, 50 μm or less) with a reduced thickness is difficult to handle, so that the productivity is likely to decrease. Furthermore, since a material with a low thermal conductivity, such as a resin, is used for the adhesive layer and it is difficult to reduce the thickness of the adhesive layer, it is difficult to improve the thermal conductivity (heat dissipation) property between portions on and under the adhesive layer.

In the case where the adhesive layer is coated as a paste, the adhesive layer is generally coated by dispensing, but with this coating method, uniform thin film coating is difficult. However, for a mixture containing a polymer compound that is incompatible with an epoxy resin, the viscosity of the ink increases, so that it is difficult to employ a coating method other than dispensing. Therefore, for a ceramic or metal filler being added to impart thermal conductivity or reduce the linear thermal expansion coefficient, there is a problem that the viscosity tends to increase further and the coatability deteriorates accordingly.

By contrast, the adhesive structure of the present embodiment has a structure in which the adhesive portion and the low elastic portion are patterned, allowing the adjustment of the arrangement of the adhesive portion and the low elastic portion. By arranging the portions to have excellent adhesiveness and heat resistance and to reduce the amount of strain in the thickness direction (inside the film) and in the plane direction (the direction substantially perpendicular to the thickness direction), the adhesive structure has excellent stress relaxation performance as well as excellent adhesiveness and heat resistance even with a thin film.

In other words, by arranging the low elastic portion for relaxing the strain of the adhesive structure to reduce the amount of strain in the film and in the plane, excellent adhesiveness, heat resistance, and stress relaxation performance can be obtained even with a thin film.

In addition, the method for manufacturing an adhesive structure of the present embodiment includes forming the adhesive portion and the low elastic portion with different inks, thereby making it possible to expand the range of ink materials for formulation to be selected and to reduce the viscosity of the ink without adding a solvent. Such a reduced viscosity of the ink makes it possible to improve the thin film coating of the adhesive structure, the filling performance, and the patterning accuracy in inkjetting, and thus reduce the generation of bubbles and voids.

In particular, the inkjetting is preferable for the coating of the adhesive portion and the low elastic portion in that it is possible to form an adhesive structure into a thin film in any pattern with excellent uniformity. In addition, applying a low-viscosity ink makes it possible to perform patterning coating while maintaining excellent filling properties in a wiring portion, for example, for wire bonding and a flip chip. This is also advantageous in that it is possible to suppress the generation of bubbles and voids, which may be starting points at which the adhesive structure peels off.

The method for manufacturing the adhesive structure of the present embodiment will be described below together with the description of the adhesive structure of the present embodiment. The present invention is not limited to the embodiment described below, may be another embodiment, and may be subject to changes such as additions, modifications, and omissions within the scope conceivable for a person skilled in the art. All of these changed configurations are also included in the scope of the present invention as long as an operation and an effect of the present invention is exhibited.

In the adhesive structure, the adhesive portion is formed to adhere to at least a contact surface of the contact object, and it is preferable that the adhesive structure have a function of maintaining an adhesive function even at high temperatures. It is also preferable that the low elastic portion has a function of relaxing thermal stress (strain) and is easily stretchable. At least one of the adhesive portion and the low elastic portion has a patterned shape, so that the adhesive function and the thermal stress relaxation function can be optimized at each portion of the adhesive structure. As a result, the adhesive structure is excellent in heat resistance with both adhesiveness and stress relaxation properties at high temperatures.

The term “patterning” as used herein means at least one of: forming a sparse and dense distribution of the adhesive portion and the low elastic portion in at least one of the thickness direction and the plane direction (the direction substantially perpendicular to the thickness direction) of the adhesive structure; and intentionally (artificially) forming the adhesive portion and the low elastic portion in a desired shape in the adhesive structure. Therefore, the “patterned shape” does not include a sea-island structure that is unintentionally (spontaneously) formed in any shape. This is due to the method for manufacturing the adhesive structure, and the patterned shape can be achieved by the method for manufacturing the adhesive structure.

The method for the patterning is not particularly limited, and may be either a method of forming the low elastic portion in a gap formed by patterning the adhesive portion or a method of forming the adhesive portion in a gap formed by patterning the low elastic portion. In the case where the adhesive structure has other members (for example, a thermally conductive portion, etc.) in addition to the adhesive portion and the low elastic portion, examples of the method for the patterning include, but are not limited to, a method of forming the low elastic portion and the other members in a gap formed by patterning the adhesive portion, and a method of forming the adhesive portion in a gap formed by patterning the low elastic portion and the other members. The order of patterning the low elastic portion and the other members is not particularly limited. Therefore, in the method for manufacturing the adhesive structure, there is no particular limitation on the order of the discharging of the adhesive portion forming ink, the discharging of the low elastic portion forming ink, and the discharging of the thermally conductive portion forming ink. These steps may be performed independently of each other, or may be performed simultaneously.

The adhesive portion is formed by discharging the adhesive portion forming ink from a nozzle, and may be formed thick by overlaying droplets of the adhesive portion forming ink on one another. In this case, the adhesive portion forming ink, the low elastic portion forming ink for forming the low elastic portion, or the thermally conductive portion forming ink for forming the thermally conductive portion described later may be coated alone. Alternatively, two or more inks selected from the adhesive portion forming ink, the low elastic portion forming ink, and the thermally conductive portion forming ink may be alternately discharged to be overlaid on one another.

The coating method for patterning the adhesive portion, the low elastic portion, and optionally the thermally conductive portion is not particularly limited and may be appropriately selected from known methods. Examples of the coating method include, but are not limited to, spin coating, casting, micro gravure coating, bar coating, roll coating, wire bar coating, dip coating, slit coating, capillary coating, inkjetting, spray coating, nozzle coating, dispense coating, gravure coating, screen printing, flexographic printing, offset printing, and reverse printing. Among these, the spray coating, the dispense coating, and the inkjetting are preferable because the spray coating, the dispense coating, and the inkjetting do not use a printing plate and can form a coating film in a non-contact manner. These coating methods enable on-demand coating according to the pattern. The inkjetting is particularly preferable in that a highly precise pattern can be formed, and at least one of the adhesive portion and the low elastic portion is more preferably formed by the inkjetting.

To improve the pattern accuracy of the adhesive portion, the low elastic portion, and optionally the thermally conductive portion, a method for patterning is preferable in which at least the adhesive portion, the low elastic portion, or the thermally conductive portion is photocured. Specifically, in the above-described method, the droplets patterned using the adhesive portion forming ink, the low elastic portion forming ink, or the thermally conductive portion forming ink are photocured over time before the droplets spread, so that the patterning accuracy is increased. At least one of: a method of photocuring in a semi-cured state; a method of overlaying photocured droplets on one another and not photocuring only the droplets on an outermost surface of the adhesive structure, which is a contact surface with the contact object; and a method of imparting adhesiveness to the post-photocured product is adopted, so that the adhesiveness of the adhesion surface (droplets on the outermost surface) at the time of adhering together can be maintained.

In particular, an inkjet printing system in which an ultraviolet light-emitting diode (UV LED) array is mounted on an inkjet head enables high-precision patterning by immediately curing discharged droplets with UV LED.

In the inkjetting, the dispense coating, or the spray coating, patterning without a plate is possible, and the adhesive portion can be directly coated on the contact object, so that the formation of the adhesive structure into a thin film and high productivity can be achieved, compared to a method of cutting and sticking a prefabricated adhesive structure. The inkjetting is excellent in fine pattern formation and film thickness uniformity and thus is a particularly preferable coating method.

By changing the pattern ratio and arrangement of the adhesive portion and the low elastic portion in the adhesive structure, the desirable adhesiveness and stress relaxation performance can be adjusted according to the contact object. In other words, since the stress (strain) of the adhesive structure is generally not uniform in the thickness direction and the plane direction, the stress relaxation performance is improved by patterning the adhesive portion and the low elastic portion. In particular, the stress caused by a difference in linear thermal expansion coefficient of an adhered object (for example, a die or a substrate) tends to concentrate on an outer circumferential end portion of the adhesive structure in the plane direction (the direction of the surface adhered to the contact object). Accordingly, the patterning is preferably performed so that at the outer circumferential end portion, the volume ratio of the volume of the low elastic portion to the volume of the adhesive portion (low elastic portion/adhesive portion) is higher than that at a central portion of the adhesive structure in the plane direction.

On the other hand, the adhesive structure may be patterned such that the outer circumferential end portion in the plane direction is the adhesive portion from the viewpoint of adhesiveness to the contact object.

In the adhesive structure, the shapes and sizes of a part of the adhesive portion and a part of the low elastic portion which are exposed on one surface may be the same as or different from the shapes and sizes of another part of the adhesive portion and another part of the low elastic portion which are exposed on another surface.

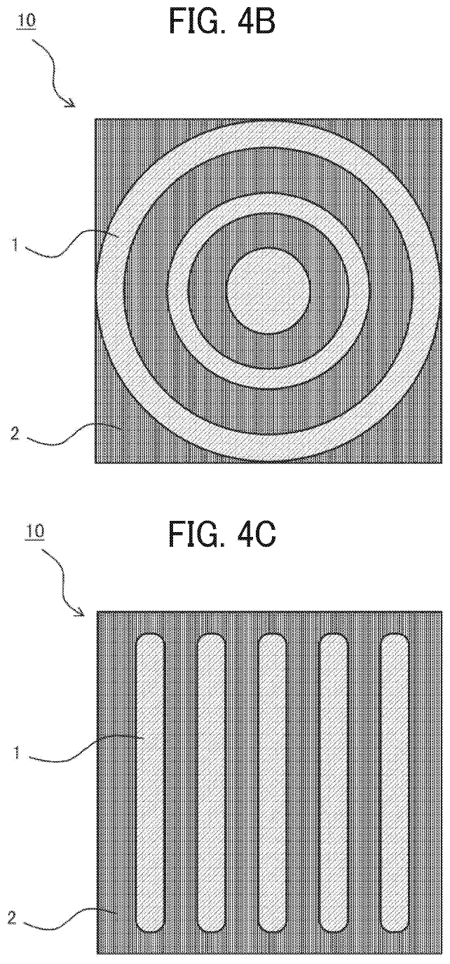

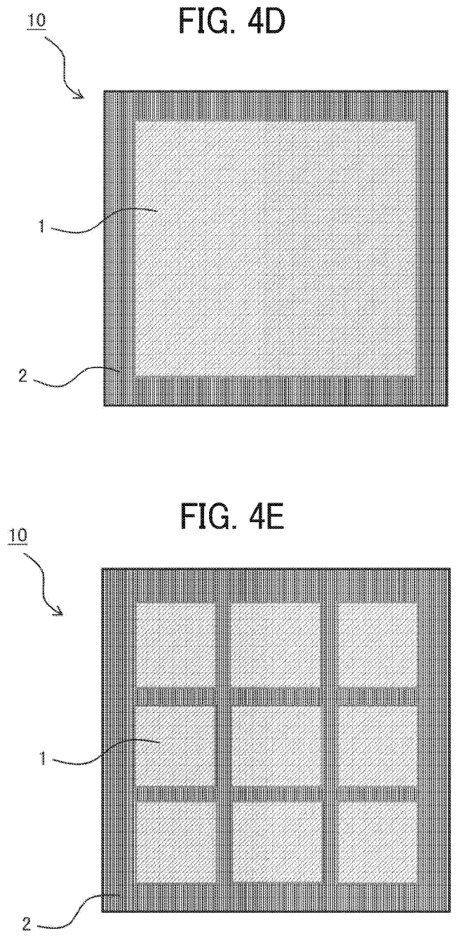

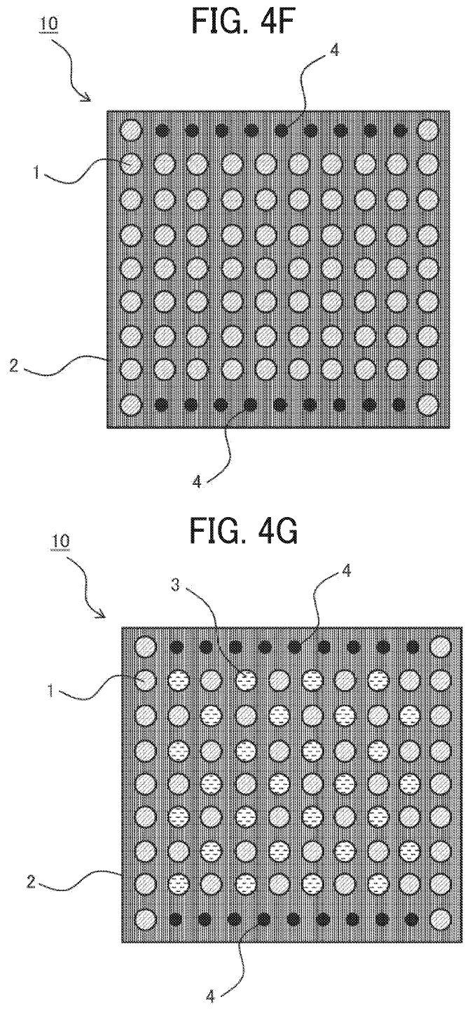

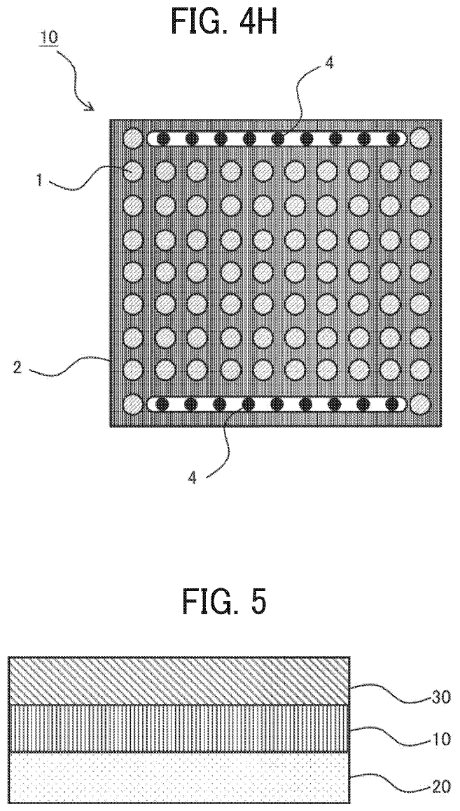

For example, the outer circumferential shape of the low elastic portion surrounded by the adhesive portion and/or the outer circumferential shape of the low elastic portion surrounded by the adhesive portion are not particularly limited and may be appropriately selected according to the purpose. Examples of the shape include, but are not limited to, any combination of shapes including straight lines, circular arcs, and elliptical arcs. Specific examples of the combination of shapes include, but are not limited to, point, line, ring, lattice, radial, circular, quadrangular, fan, columnar, and conical shapes (see FIGS. 4A to 4H).

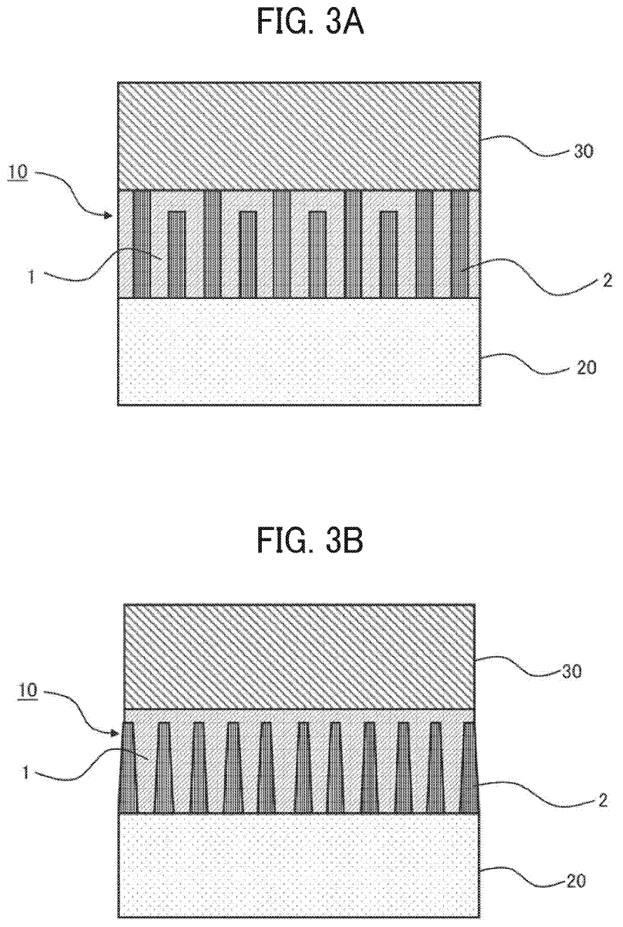

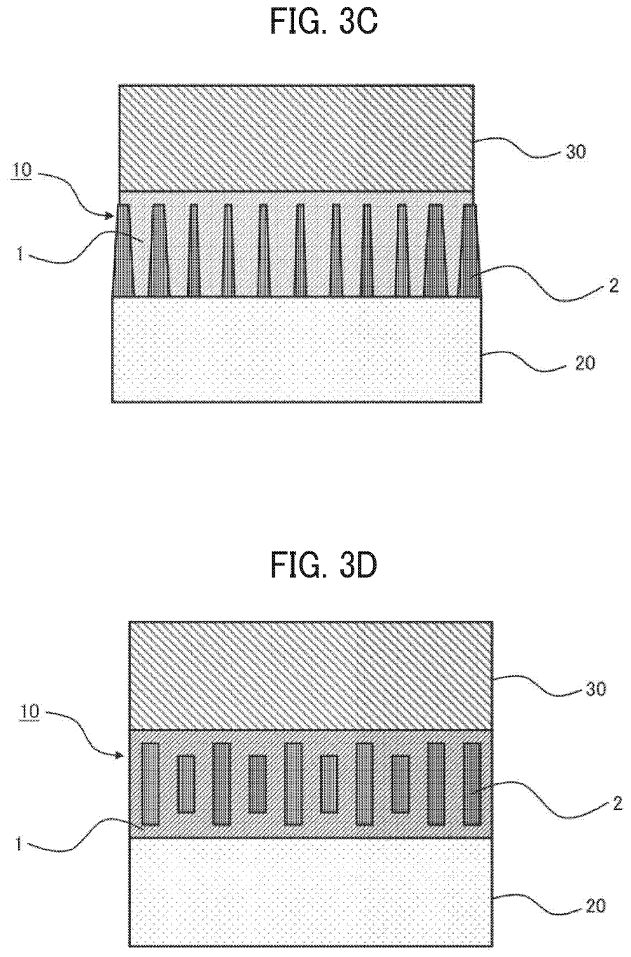

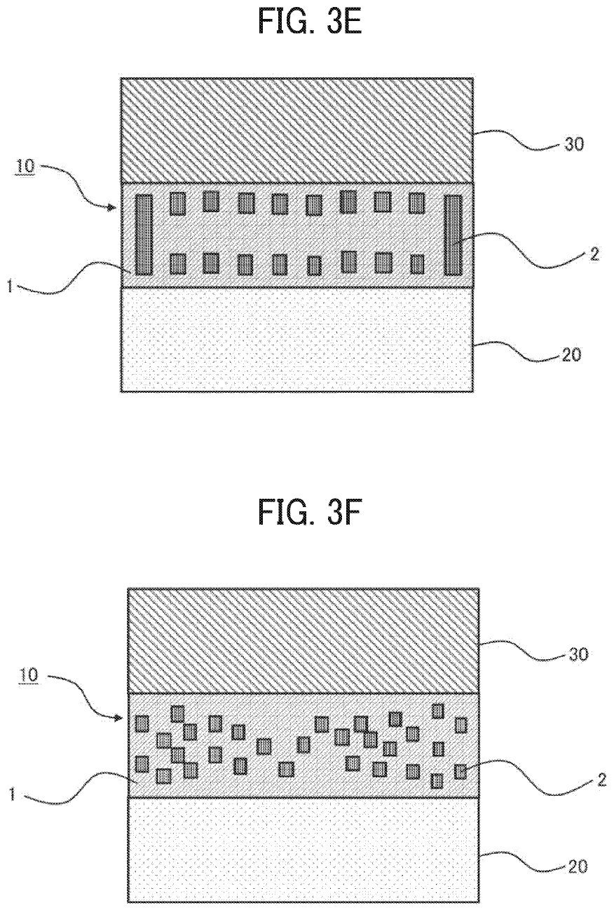

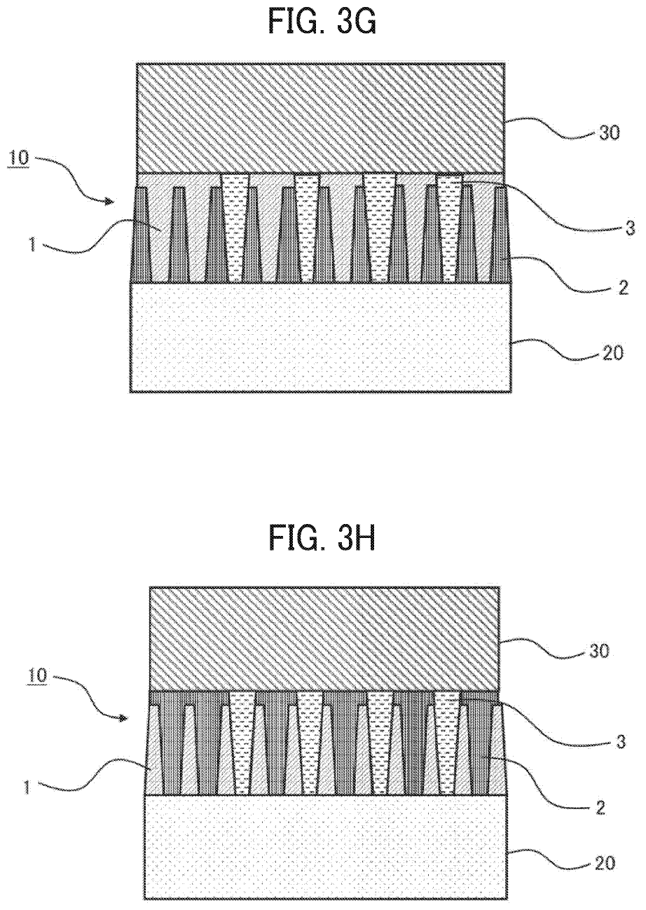

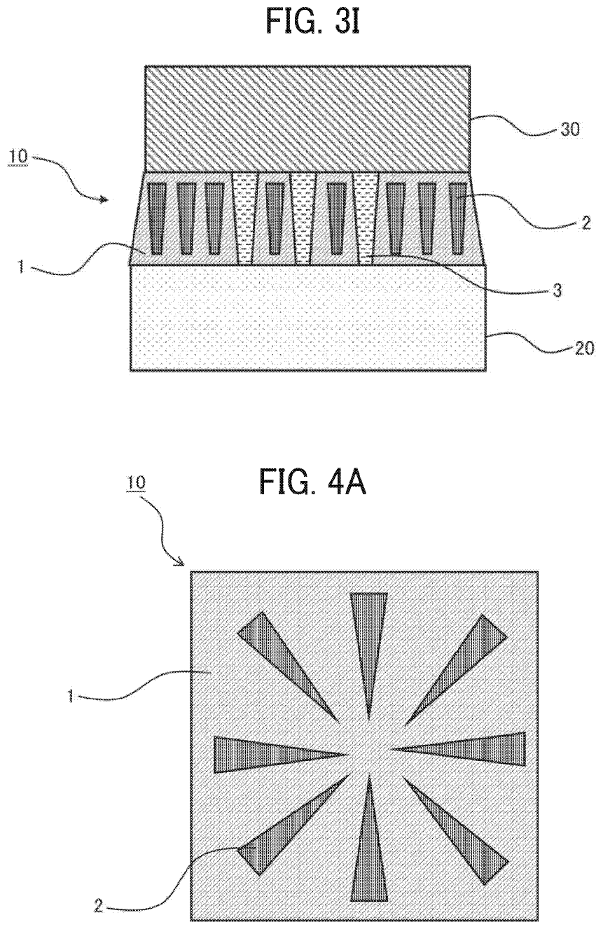

The low elastic portion may not be exposed on a surface of the adhesive structure. Specifically, the low elastic portion may be patterned in the thickness direction or the plane direction of the adhesive structure (the direction substantially perpendicular to a cross section in the thickness direction, not exposed on a surface of the adhesive structure). Also in this case, the outer circumferential shape of the low elastic portion surrounded by the adhesive portion are not particularly limited and may be appropriately selected according to the purpose. Examples of the shape include, but are not limited to, any combination of shapes including straight lines, circular arcs, and elliptical arcs. Specific examples of the combination of shapes include, but are not limited to, point, line, ring, lattice, radial, circular, quadrangular, fan, columnar, and conical shapes (see FIGS. 3A to 3I).

The shape of the adhesive structure can be confirmed by mapping analysis in cross-sectional and plane directions using Fourier transform infrared spectroscopy (FT-IR).

The shape of the adhesive structure is not particularly limited as long as the adhesive portion and the low elastic portion are patterned and may be appropriately selected according to the purpose. Examples of the shape include a layered shape and a blocked shape.

The term “layered” as used herein refers to a thickness of 1,000 μm or less, and the term “blocked” refers to a thickness of more than 1,000 μm. These shapes may be appropriately selected according to an intended usage. For example, a layered adhesive structure can be suitably used for bonding between a semiconductor (die) that is suitably formed as a thin film and various materials to adhere to the semiconductor (die).

For a layered adhesive structure, its thickness is 1,000 μm or less, preferably from 1 μm to 500 μm, and more preferably from 1 μm to 50 μm in view of the demand for reducing the thickness and from the viewpoint of reducing the heat resistance. The thickness of the adhesive structure can be measured with a stylus meter (Alpha-Step D-500, manufactured by KLA-Tenchore), an optical reflectance spectrometer (F50, manufactured by Filmetrics), or the like. The term “thickness” as used herein means an “average thickness” obtained by measuring thicknesses at any three points with the stylus meter and calculating an average of them.

### <Adhesive Portion and Adhesive Portion Forming Step>

The adhesive portion is a member to adhere to a contact object. The adhesive portion is suitably formed in the discharging of the adhesive portion forming ink.

The discharging of the adhesive portion forming ink is a step of discharging an adhesive portion forming ink for forming an adhesive portion to adhere to a contact object, from a nozzle, to form the adhesive portion.

The contact object is not particularly limited and may be appropriately selected according to the purpose. Examples of the contact object include a heat-generating component, a cooling component, a substrate, and an electrode.

The material forming the adhesive portion is not particularly limited and may be appropriately selected according to the purpose, but the adhesive portion preferably contains a resin having an adhesive function, and further optionally contains other materials, from the viewpoint of obtaining mechanical adhesive strength.

### <<Resin>>

The resin having an adhesive function is not particularly limited and may be appropriately selected according to the purpose. Examples of the resin include photocurable resins and thermosetting resins. Each of these may be used alone or in combination with others. In particular, if the optical transparency at the adhesion surface between the adhesive portion and the contact object is not suitable for photocuring through the contact object, the adhesive portion preferably contains at least a thermosetting resin. At least one of the adhesive portion and the low elastic portion preferably contains a photocurable resin.

Specific examples of the resin include, but are not limited to, a urethane-based resin, an epoxy-based resin, a phenol-based resin, a polyimide-based resin, an ester-based resin, a vinyl-based resin, a silicone-based resin, a styrene-based resin, a cellulose-based resin, an amide-based resin, a (meth)acrylic-based resin, a melamine-based resin, and a fluoro-based resin. Each of these may be used alone or in combination with others. Among these resins, an epoxy-based resin, a silicone-based resin, and a polyimide-based resin are preferable in view of their good heat resistance, and an epoxy-based resin is more preferable in view of its small cure shrinkage.

An adhesive portion forming ink containing monomer component of the resin can be used to form the adhesive portion by applying the adhesive portion forming ink to the contact object to be subjected to a polymerization reaction.

### <<<Adhesive Portion Forming Ink>>>

The adhesive portion forming ink may contain the resin, may contain the monomer component of the resin and a polymerization initiator, and may further optionally contain other components. However, it is preferable to contain the monomer component of the resin and the polymerization initiator in view of good performance of patterning.

### —Monomer Component—

The monomer component of the resin is not particularly limited and may be appropriately selected according to the type of resin to be used. Examples of the monomer component include, but not limited to, an epoxy monomer, a (meth)acrylate monomer, an oxetane monomer, a urethane monomer, and a silicone monomer. Each of these may be used alone or in combination with others. Among these, an epoxy monomer is preferably contained as the monomer component of the resin. In the present disclosure, “acrylate monomers and methacrylate monomers” are collectively referred to as “(meth)acrylate monomers”.

### —Epoxy Monomer—

The epoxy monomer is not particularly limited and may be appropriately selected according to the purpose. Examples of the epoxy monomer include, but are not limited to, an alicyclic epoxy monomer, a glycidyl ether type epoxy monomer, and a glycidyl amine type epoxy monomer. The alicyclic epoxy monomer has a high glass transition temperature (Tg), is excellent in heat resistance, and has a low monomer viscosity because of its ring structure.

The glycidyl ether type epoxy monomer is easily adjusted such that the resulting cured product has a low elastic modulus, and has a low monomer viscosity. The glycidyl amine type epoxy monomer easily has an adhesive strength. By mixing various epoxy monomers having the above characteristics, an adhesive portion forming ink suitable for inkjetting can be obtained.

Examples of the alicyclic epoxy monomer include, but not limited to, compounds represented by any one of Structural Formulas 1 to 16 below. Each of these may be used alone or in combination with others.

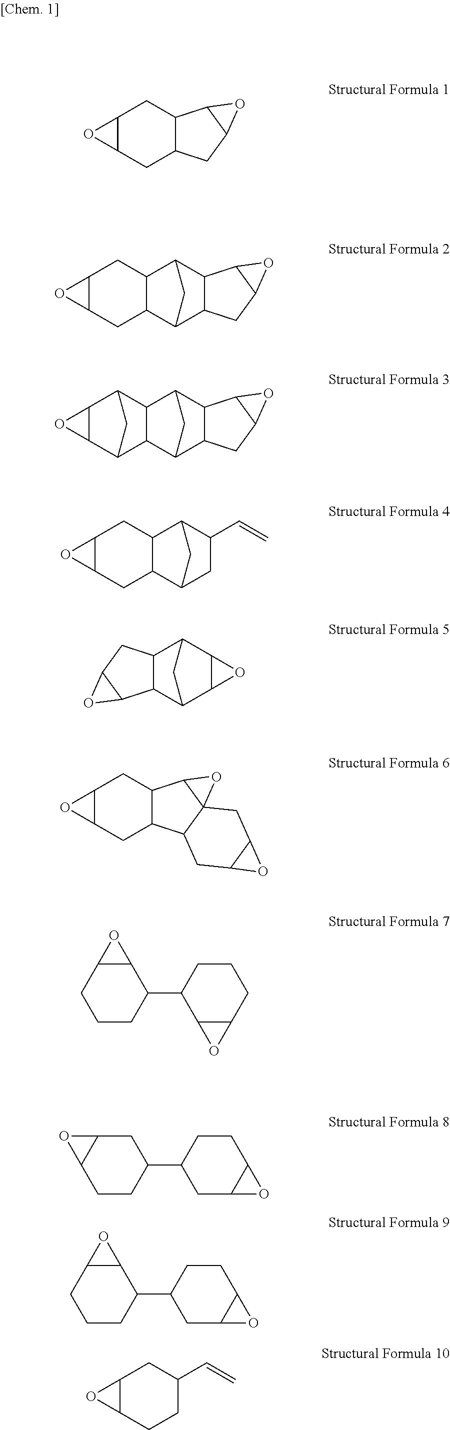

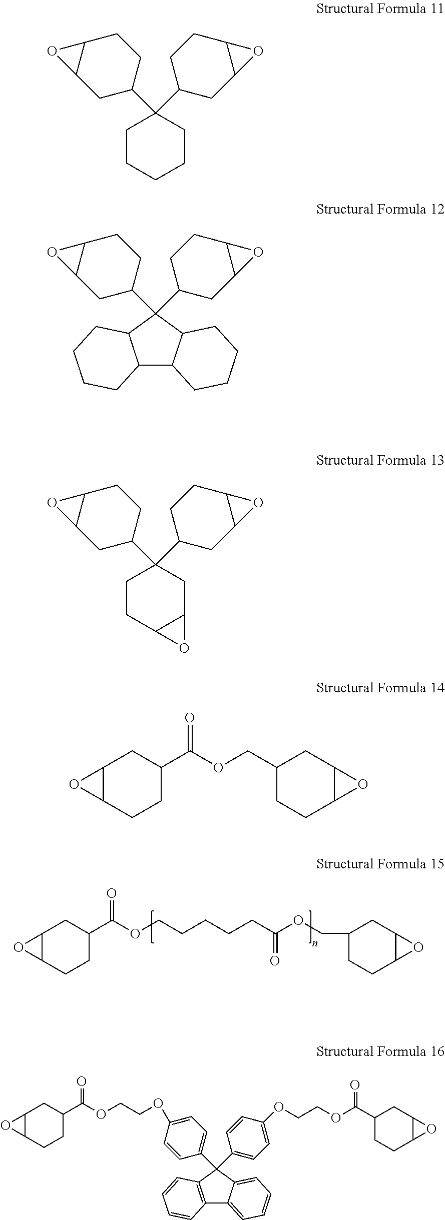

Wherein in Structural Formula 15, n represents an integer of 1 or 2.

As the alicyclic epoxy monomer, an appropriately synthesized alicyclic epoxy monomer may be used, or a commercially available alicyclic epoxy monomer may be used. Examples of the commercially available alicyclic monomer include, but are not limited to, EPOCHALIC THI-DE, EPOCHALIC DE-102, EPOCHALIC DE-103, VNBB-ME (manufactured by ENEOS Corporation), DCPD-DE (manufactured by Japan Material Technologies Corporation), CELLOXIDE (CEL) 8010P, CEL2010P, CEL2081, and CEL2000 (manufactured by Daicel Corporation).

Examples of the glycidyl ether type epoxy monomer include, but are not limited to, allyl diglycidyl ether and bisphenol type diglycidyl ether. Specific examples of the glycidyl ether type epoxy monomer include, but are not limited to, compounds represented by any one of structural formulas 17 to 22 below. Each of these may be used alone or in combination with others.

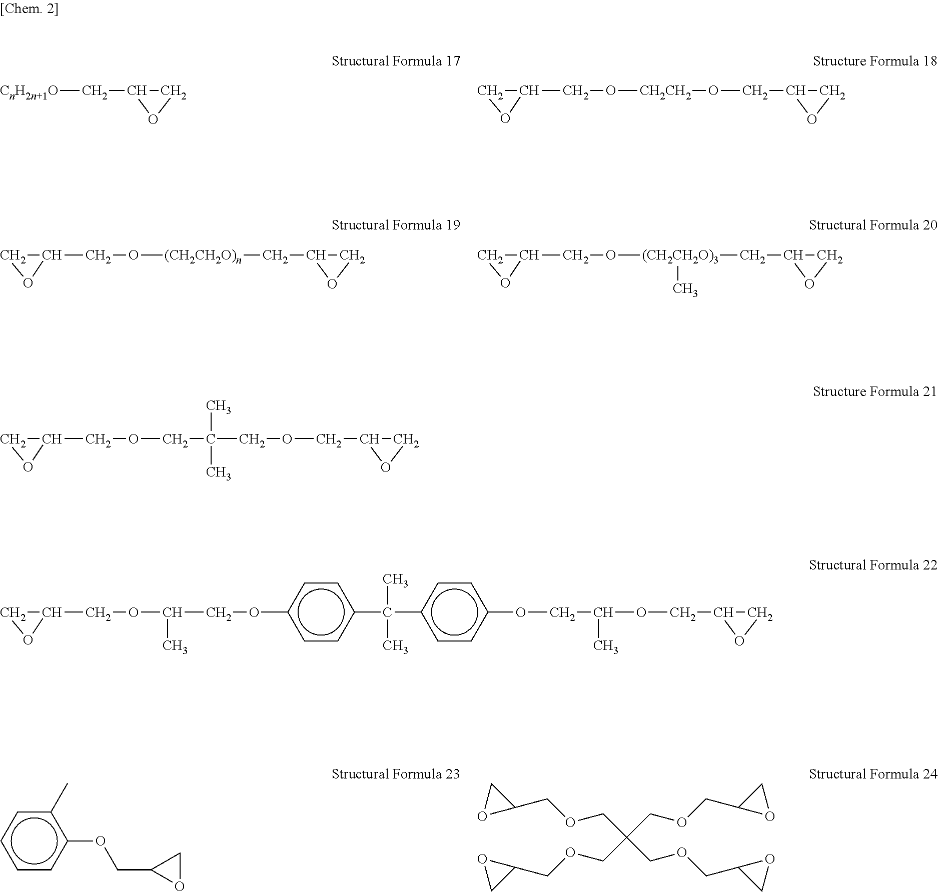

Wherein in Structural Formula 17, n represents 12, and in Structural Formula 19, n represents 9.

As the glycidyl ether type epoxy monomer, an appropriately synthesized glycidyl ether type epoxy monomer may be used, or a commercially available glycidyl ether type epoxy monomer may be used. Examples of the commercially available glycidyl ether type epoxy monomer include, but are not limited to, RIKARESIN DME-100 (manufactured by New Japan Chemical Co., Ltd.), EPOLIGHT M-1230, EPOLIGHT 40E, EPOLIGHT 100E, EPOLIGHT 200E, EPOLIGHT 400E, EPOLIGHT 70P, EPOLIGHT 200P, EPOLIGHT 400P, EPOLIGHT 1500NP, EPOLIGHT 1600, EPOLIGHT 80MF, EPOLIGHT 100MF (manufactured by Kyoeisha Chemical Co., Ltd.), SHOFREE PETG, SHOFREE BATG (manufactured by Showa Denko K.K.), DENACOL EX-614B, DENACOL EX-313, DENACOL EX-512, DENACOL EX-321, DENACOL EX-321L, DENACOL EX-612, DENACOL EX-614, DENACOL EX-622, DENACOL EX-314, DENACOL EX-421, DENACOL EX-521, DENACOL EX-411, DENACOL EX-171, DENACOL EX-146, DENACOL EX-121, DENACOL EX-141, DENACOL EX-145, DENACOL EX-147, DENACOL EX-192, DENACOL EX-731 (manufactured by Nagase ChemteX Corporation), YL9028 (manufactured by Mitsubishi Chemical Corporation), OCR-EP, NPG (D), DY-BP, and DY-BP (manufactured by Yokkaichi Chemical Co., Ltd.).

The glycidyl amine type epoxy monomer has an amine structure. As the glycidyl amine type epoxy monomer, an appropriately synthesized glycidyl amine type epoxy monomer may be used, or a commercially available glycidyl amine type epoxy monomer may be used. Examples of the commercially available glycidyl amine type epoxy monomer include, but are not limited to, TETRAD-X (manufactured by Mitsubishi Gas Chemical Company, Inc.) and VH-523 (manufactured by Nippon Steel Chemical & Material Co., Ltd.).

### —(Meth)acrylate Monomer—

The (meth)acrylate monomer is not particularly limited and may be appropriately selected from general photopolymerization type (meth)acrylate monomers according to the purpose. Each of these may be used alone or in combination with others.

As the (meth)acrylate monomer, an appropriately synthesized (meth)acrylate monomer may be used, or a commercially available (meth)acrylate monomer may be used. Examples of the commercially available (meth)acrylate monomer include, but are not limited to, AOMA (manufactured by Nippon Shokubai Co., Ltd.), HEA (hydroxyethyl acrylate), HPA (hydroxypropyl acrylate), 4-HBA (4-hydroxybutyl acrylate), AIB (isobutyl acrylate), TBA (t-butyl acrylate), NOAA (n-octyl acrylate), INAA (isononyl acrylate), Viscoat #197 (nonyl acrylate), IDAA (nonyl acrylate), LA (lauryl acrylate), STA (stearyl acrylate), ISTA (isostearyl acrylate), IBXA (isobornyl acrylate), Viscoat #155 (cyclohexyl acrylate), Viscoat #196 (3,3,5-trimethylcyclohexyl acrylate), Viscoat #160 (benzyl acrylate), Viscoat #192 (phenoxyethyl acrylate), Viscoat #150 (tetrahydrofurfuryl acrylate), Viscoat #190 (ethyl carbitol acrylate), 2-MTA (methoxyethyl acrylate), Viscoat #MTG (methoxytriethylene glycol acrylate), MPE400A (methoxy polyethylene glycol acrylate), MPE550A (methoxy polyethylene glycol acrylate), OXE-10 ((3-ethyloxetane-3-yl)methyl acrylate), OXE-30 ((3-ethyloxetane-3-yl)methyl methacrylate), MEDOL-10 ((3-ethyloxetan-3-yl)methyl acrylate), Viscoat #200 (cyclic trimethylolpropane formal acrylate) (manufactured by Osaka Organic Chemical Industry Ltd.), A-LEN-10 (ethoxylated-o-phenylphenol acrylate), AM-90G (ethoxylated-o-phenylphenol acrylate), AM-130G (ethoxylated-o-phenylphenol acrylate), AMP-20GY (ethoxylated-o-phenylphenol acrylate), A-SA (2-acryloyloxyethyl succinic acid), 701A (2-hydroxy-3-methacrylpropyl acrylate), A-200 (polyethylene glycol #200 diacrylate), A-400 (polyethylene glycol #400 diacrylate), A-600 (polyethylene glycol #600 diacrylate), A-100 (polyethylene glycol #100 diacrylate), ABE-300 (ethoxylated bisphenol A diacrylate), A-BPE-10 (ethoxylated bisphenol A diacrylate), A-BPE-20 (ethoxylated bisphenol A diacrylate), A-BPE-4 (ethoxylated bisphenol A diacrylate), A-DCP (tricyclodecane dimethanol diacrylate), A-DOD-N (1,10-decane diol diacrylate), A-HD-N (1,6-hexanediol diacrylate), A-NOD-N (1,6-hexanediol diacrylate), APG-200 (tripropylene glycol diacrylate), APG-400 (polypropylene glycol #400 diacrylate), APG-700 (polypropylene glycol #700 diacrylate), A-PTMG-65 (polytetramethylene glycol #650 diacrylate), A-9300 (polytetramethylene glycol #650 diacrylate), A-GLY-9E (ethoxylated glycerol triacrylate), A-GLY-20E (ethoxylated glycerol triacrylate), A-TMM-3 (pentaerythritol tri- or tetra-acrylate), A-TMM-3L (pentaerythritol tri- or tetra-acrylate), A-TMPT (trimethylolpropane triacrylate), AD-TMP (ditrimethylolpropane tetraacrylate), ATM-35E (ethoxylated pentaerythritol tetraacrylate), A-TMMT (pentaerythritol tetraacrylate), A-9550 (dipentaerythritol polyacrylate), A-DPH (dipentaerythritol polyacrylate) (manufactured by Shin-Nakamura Chemical Co., Ltd.).

### —Oxetane Monomer—

The oxetane monomer is not particularly limited and may be appropriately selected according to the purpose. Examples of the oxetane monomer include, but are not limited to, compounds represented by any one of structural formulas 25 to 33 below. Each of these may be used alone or in combination with others.

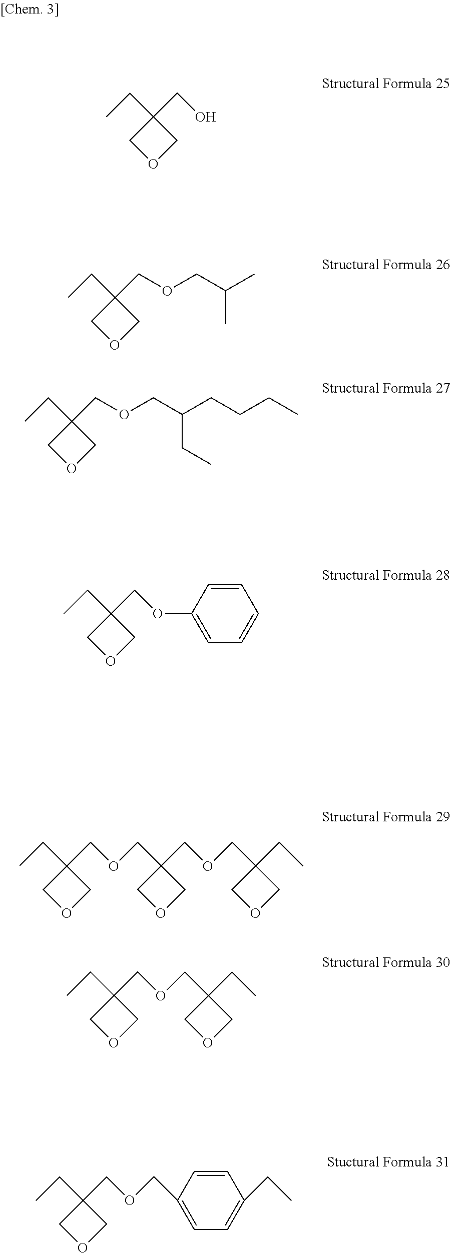

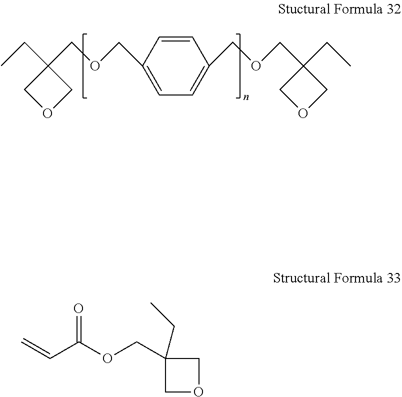

Wherein in Structural Formula 32, n represents an integer of 1 or 2.

As the oxetane monomer, an appropriately synthesized oxetane monomer may be used, or a commercially available oxetane monomer may be used. Examples of the commercially available oxetane monomer include, but are not limited to, ARON OXETANE OXT101, ARON OXETANE OXT212, ARON OXETANE OXT121, ARON OXETANE OXT221 (manufactured by Toagosei Co., Ltd.), ETERNACOLL HBOX, ETERNACOLL OXBP, and ETERNACOLL OXIPA (manufactured by UBE Corporation).

### —Urethane Monomer—

The urethane monomer is not particularly limited and may be appropriately selected from general urethane monomers according to the purpose. Each of these may be used alone or in combination with others.

As the urethane monomer, an appropriately synthesized urethane monomer may be used, or a commercially available urethane monomer may be used. Examples of the commercially available urethane monomer include, but are not limited to, US3003, US3003M, US3007, US3007M, and US3123M (manufactured by Kyoeisha Chemical Co., Ltd.).

### —Silicone Monomer—

The silicone monomer is not particularly limited and may be appropriately selected from general silicone monomers according to the purpose. Examples of the silicone monomer include, but are not limited to, a silicone compound having reactive groups at one or both terminals of polydimethylsiloxane. Each of these may be used alone or in combination with others.

As the silicone monomer, an appropriately synthesized silicone monomer may be used, or a commercially available silicone monomer may be used. Examples of the commercially available silicone monomer include, but are not limited to, SILAPLANE FM-3311, SILAPLANE FM-3321, SILAPLANE FM-3325 (manufactured by JNC Corporation), STP-103-UV, and STP-104-UV (manufactured by Shin-Etsu Chemical Co., Ltd.).

The adhesive portion forming ink preferably contains an epoxy monomer as described above. The content of the epoxy monomer in the adhesive portion forming ink is not particularly limited and may be appropriately selected according to the purpose, but is preferably 40 mass % or more and is more preferably 50 mass % or more, based on the total mass of an adhesive portion forming ink. It is preferable to have the content of epoxy monomer of 40 mass % or more in view of small cure shrinkage and excellent heat resistance.

In a case where the monomer component in the adhesive portion forming ink is a mixture of the epoxy monomer and a monomer component other than the epoxy monomer, the content of the monomer other than the epoxy monomer is not particularly limited and may be appropriately selected according to the purpose, but is preferably from 5 mass % to 90 mass %, and more preferably from 5 mass % to 70 mass %, based on the epoxy monomer.

As the monomer component other than the epoxy monomer, an oxetane compound is preferable in view of excellent compatibility with the epoxy monomer and low viscosity.

### —Polymerization Initiator—

The polymerization initiator is not particularly limited and may be appropriately selected from known polymerization initiators. Examples of the polymerization initiator include, but are not limited to, a photo-cationic polymerization initiator, a photo-radical polymerization initiator, and a thermal polymerization initiator. Each of these may be used alone or in combination with others.

### —Photo-Cationic Polymerization Initiator—

The photo-cationic polymerization initiator is not particularly limited and may be appropriately selected according to the purpose. Examples of the photo-cationic polymerization initiator include, but are not limited to, a photoacid generator such as an onium salt having a sulfonium ion and an iodonium ion as a cationic part. Among these, as the photo-cationic polymerization initiator, a compound having an anionic part that is less corrosive to metal portions is preferable. Specific examples of the photo-cationic polymerization initiator include, but are not limited to, a compound containing B(C₆F₅)₄ or PF₃(C₂F₅)₃ as an anionic part (generated acid).

As the photo-cationic curable initiator, an appropriately synthesized photo-cationic curable initiator may be used, or a commercially available photo-cationic curable initiator may be used. Examples of the commercially available photo-cationic curable initiator include, but are not limited to, CPI-110P, CPI-110A, CPI-210S, CPI-110B, CPI-310B, CPI-410B, CPI-310FG, and IK-1FG (manufactured by San-Apro Ltd.).

### —Photo-Radical Polymerization Initiator—

The photo-radical polymerization initiator is not particularly limited and may be appropriately selected according to the purpose. Examples of the photo-radical polymerization initiator include, but are not limited to, an alkylphenone compound, an acylphosphine oxide compound, and an oxyphenyl acetic acid ester compound.

As the photo-radical polymerization initiator, an appropriately synthesized photo-radical polymerization initiator may be used, or a commercially available photo-radical polymerization initiator may be used. Examples of the commercially available photo-radical polymerization initiator include, but are not limited to, OMNIRAD 184 (former IRGACURE 184), OMNIRAD 651 (former IRGACURE 651), OMNIRAD 1173 (former IRGACURE 1173), OMNIRAD 2959 (former IRGACURE 2959), OMNIRAD 369 (former IRGACURE 369), OMNIRAD 907 (former IRGACURE 907), OMNIRAD BMS, OMNIRAD DETX, OMNIRAD TPO H (former IRGACURE TPO), OMNIRAD 819 (former IRGACURE 819) (manufactured by IGM Resins B.V.), IRGACURE OXE01, IRGACURE OXE02, IRGACURE OXE03, and IRGACURE OXE04 (manufactured by BASF Japan Ltd.).

### —Thermal Polymerization Initiator—

The thermal polymerization initiator is not particularly limited and may be appropriately selected according to the purpose. Examples of the thermal polymerization initiator include, but are not limited to, a photoacid generator such as an onium salt having a sulfonium ion and an iodonium ion as a cationic part.

As the thermal polymerization initiator, an appropriately synthesized thermal polymerization initiator may be used, or a commercially available thermal polymerization initiator may be used. Examples of the commercially available thermal polymerization initiator include, but are not limited to, SAN-AID SI-60L, SAN-AID SI-80L, SAN-AID SI-100L, SAN-AID SI-110, and L-SAN-AID SI-150 (manufactured by Sanshin Chemical Industry Co., Ltd.), TA-100, TA-100FG, IK-1, IK-1FG (manufactured by San-Apro Ltd.), Omnicat 250 (former IRGACURE 250), and Omnicat 270 (former IRGACURE 270) (manufactured by IGM Resins B.V.).

The content of the polymerization initiator in the adhesive portion forming ink is not particularly limited and may be appropriately selected according to the purpose, but is preferably from 0.1 mass % to 10 mass %, and more preferably from 0.2 mass % to 2 mass %, based on the total mass of the adhesive portion forming ink. In a case where the content of the polymerization initiator is from 0.1 mass % to 10 mass %, the curing reaction can be appropriately completed, and unreacted components are less likely to remain as reactive impurities.

### Other Components

The other components in the adhesive portion forming ink are not particularly limited and may be appropriately selected according to the purpose. Examples of the other components include inorganic particles, resins or resin particles, adhesion improvers, and solvents. Each of these may be used alone or in combination with others.

### —Inorganic Particle—

The inorganic particle is added to reduce a linear thermal expansion coefficient of the adhesive portion and improve the film strength. The inorganic particle is not particularly limited and may be appropriately selected according to the purpose. Examples of the inorganic particle include, but are not limited to, a ceramic material and a magnetic particle. Examples of the ceramic material include, but are not limited to, silica (SiO₂), aluminum oxide (Al₂O₃), aluminum nitride (AlN), and boron nitride (BN). The ceramic material has a smaller linear thermal expansion coefficient and higher softening temperature as compared to the resin material, and thus it is possible to obtain an effect of reducing the linear thermal expansion coefficient of the adhesive portion and improving the film strength at high temperature. Examples of the magnetic particle include, but are not limited to, iron (Fe), nickel (Ni), and cobalt (Co). The magnetic particle can impart a function of shielding electromagnetic waves. Each of these may be used alone or in combination with others.

As the inorganic particle, an appropriately synthesized inorganic particle may be used, or a commercially available inorganic particle may be used. Examples of the commercially available inorganic particle include, but not limited to, AEROSIL OX50, AEROSIL 50, AEROSIL 90G, AEROSIL 130, AEROSIL 150, AEROSIL 200, AEROSIL 300, AEROSIL 380, AEROSIL RM50, AEROSIL R711, AEROSIL R7200, AEROXIDE P25, AEROXIDE P90 AluC (manufactured by Nippon Aerosil Co., Ltd.), SEAHOSTAR KE-S10, SEAHOSTAR S30, and SEAHOSTAR S50 (manufactured by Nippon Shokubai Co., Ltd.).

The content of the inorganic particle is not particularly limited and may be appropriately selected according to the purpose, but is preferably from 10 mass % to 70 mass % and more preferably from 10 mass % to 50 mass %, based on the total mass of the adhesive portion forming ink. In a case where the content of the inorganic particle is 10 mass % or more, the effects of linear thermal expansion and film strength can be easily obtained, and in a case where the content of the inorganic particle is 50 mass % or less, the adhesive portion is less likely to be brittle and the ink viscosity is less likely to be increased, which are thus preferable.

### —Resin or Resin Particle—

The resin or resin particle is added to impart flexibility to the adhesive portion and to relieve thermal stress. The resin or resin particle is not particularly limited and may be appropriately selected according to the purpose, but a material containing a straight-chain polymer having at least one of low elasticity and flexibility is preferable. Examples of such a resin include, but are not limited to, a styrene-butadiene-based resin, an acrylonitrile-butadiene-based resin, a (meth)acrylic-based resin, and an epoxy resin. Each of these may be used alone or in combination with others. In addition, a polymer particle having a core-shell type multilayered structure in which a rubber-like polymer is arranged inside an acrylic copolymer may be used. Among these, the styrene-butadiene-based resin and the acrylic-based resin are preferable as the resin or resin particle. The resin or resin particle is preferable in view of having a low glass transition temperature (Tg) to relax thermal stress, which is about 30° C. or less and is nearly equal to the room temperature.

Here, the resin or resin particle having “low elasticity” means a material having elastic modulus of 200 MPa or less, for example. The resin or resin particle having “flexibility” means a material having the power of elastic deformation of 70% or more. The elastic deformation work rate of the resin and resin particle can be confirmed, for example, by measuring the indentation elastic modulus with a microhardness tester (for example, FISCHERSCOPE HM2000, manufactured by Fisher Instruments Co., Ltd.).

As the resin material having low elasticity, an appropriately synthesized resin material may be used, or a commercially available resin material may be used. Examples of the commercially available resin material having low elasticity include, but are not limited to, ARUFON US-1000, ARUFON UH-2000, ARUFON UC-3000, ARUFON UG-4000, ARUFON UF-5000, and ARUFON US-600.

As the resin particle having low elasticity, an appropriately synthesized resin particle may be used, or a commercially available resin particle may be used. Examples of the commercially available resin particle having low elasticity include, but are not limited to, KANE ACE MX-150, KANE ACE MX-553 (manufactured by Kaneka Corporation), FINE SPHERE MG-155, FINE SPHERE MG-351, FINE SPHERE MG-451, FINE SPHERE MG-651, FINE SPHERE PZP-1003, FINE SPHERE BGK-001 (manufactured by Nippon Paint Industrial Coatings Co., Ltd.), METABLEN C-223A, METABLEN C-215AC-201A, METABLEN C-140A, METABLEN E-860A, METABLEN E-870A, METABLEN E-875A, METABLEN W-300A, METABLEN W-450A, METABLEN W-600A, METABLEN W-377, METABLEN S-2002, METABLEN S-2006, METABLEN S-2501, METABLEN S-2030, METABLEN S-2100, METABLEN S-2200, METABLEN SRK200A, METABLEN SX-006, METABLEN SX-00 (manufactured by Mitsubishi Chemical Corporation), ZEFIAC F351, STAPHYLOID AC-3355, AC-3816N, AC-3832SD, AC-4030, and AC-3388 (manufactured by Aica Kogyo Company, Limited).

The content of the resin or resin particle in the adhesive portion forming ink is not particularly limited and may be appropriately selected according to the purpose, but is preferably from 1 mass % to 50 mass % and more preferably from 3 mass % to 20 mass %, based on the total mass of the adhesive portion forming ink. In a case where the content of the resin or resin particle is 1 mass % or more, the thermal stress can be relaxed more suitably. In a case where the content of the resin or resin particle is 50 mass % or less, it is possible to suppress an increase in the viscosity of the adhesive portion forming ink, and thus, the ink is suitably used for the inkjet method. In addition to that, the content of 50 mass % or less is less likely to cause bubbles and voids at high temperatures.

### —Adhesion Improver—

The adhesion improver is a compound constituted of an organic substance and silicon, and a silane coupling agent having two or more different reactive groups in the molecule is particularly preferable in view of improving adhesiveness against a contact target (particularly, a semiconductor and a semiconductor substrate). Commercially available products can be used as the adhesion improver, and specific examples include, but are not limited to, DOWSIL Z-6040, DOWSIL Z-6062 (manufactured by DOW), and KMB-403 (manufactured by Shin-Etsu Chemical Co., Ltd.).

The content of the adhesion improver in the adhesive portion forming ink is not particularly limited and may be appropriately selected according to the purpose, but is preferably from 0.1 mass % to 20 mass % and more preferably from 0.1 mass % to 5 mass %, based on the total mass of the adhesive portion forming ink. In a case where the content of the adhesion improver is 0.1 mass % or more, an adhesion effect can be obtained. The content of the adhesion improver is preferably 20 mass % or less in view of suppressing the decrease in ink strength.

### —Solvent—

The solvent is not particularly limited and may be appropriately selected according to the purpose. Examples of the solvent include, but are not limited to, terpineol, 1-methoxy-2-propanol, diethylene glycol monomethyl ether, triethylene glycol monomethyl ether, acetic acid-2-methoxyethyl, acetic acid-2-methoxybutyl, and 2-butanone. Each of these may be used alone or in combination with others.

The content of the solvent in the adhesive portion forming ink is not particularly limited and may be appropriately selected according to the purpose, but the solvent is preferably not contained when the viscosity of the adhesive portion forming ink is appropriate. In a case where the solvent is added, the added amount is preferably from 1 mass % to 30 mass % and more preferably from 1 mass % to 5 mass %, based on the total mass of the adhesive portion forming ink. In a case where the content of the solvent is 1 mass % or more, it is possible to easily manage the solvent component of the adhesive portion forming ink and to lower the viscosity, and thus, the ink is suitably used for the inkjet method. In addition to that, the content of 30 mass % or less is less likely to cause bubbles and voids at high temperatures.

Among these, the adhesive portion forming ink preferably has a photocurable composition, and preferably contains the epoxy monomer, and the photo-cationic polymerization initiator or the photo-radical polymerization initiator.

The viscosity of the adhesive portion forming ink is not particularly limited and may be appropriately selected according to the purpose, but is preferably low enough to be discharged from a small-diameter nozzle in inkjetting. The viscosity is preferably 200 mPa·s or less in the environment of 25° C. and more preferably 50 mPa·s or less. In addition, the lower limit of the viscosity of the adhesive portion forming ink is not particularly limited and may be appropriately selected according to the purpose, but is preferably 5 mPa·s or more in the environment of 25° C. in the view of the discharging performance and the fabrication accuracy.

The viscosity of the adhesive portion forming ink can be measured by a conventional method, and for example, the method described in Japanese Industrial Standards (JIS) Z 8803 can be used. As another example, a cone rotor (1° 34′×R24) in a cone and plate type rotational viscometer (for example, VISCOMETER TVE-22L, manufactured by Toki Sangyo Co., Ltd.) can be used to measure the viscosity at a rotation speed of 10 rpm under constant temperature circulating water appropriately set within the range of 20° C. to 65° C. To adjust the temperature of the circulating water, a circulating constant temperature bath (for example, VISCOMATE VM-150III, manufactured by Toki Sangyo Co., Ltd.) can be used.

The adhesive portion may be disposed on only one surface of the adhesive structure in the plane direction, or may be disposed on both surfaces, as long as the adhesive portion can be adhered to the contact object. The adhesive portion is patterned in a portion where the low elastic portion is not formed on the surface adhered to the contact object. In a case where the adhesive structure has the thermally conductive portion, the adhesive portion is patterned in a portion where the low elastic portion and the thermally conductive portion are not formed on the surface adhered to the contact object. In a case where the adhesive structure has a wiring portion, for example, for wire bonding and a flip chip, the adhesive portion may be not formed in an area where the wiring portion is formed.

The size of the adhesive portion in the adhesive structure in the plane direction is not particularly limited and may be appropriately selected according to the purpose, but is preferably equal to or greater than the thickness of the adhesive structure including the adhesive portion and the low elastic portion to obtain an adhesive strength. The size of the adhesive portion in the adhesive structure in the plane direction is preferably 10 μm or more, and more preferably 100 μm or more. In a case where the size of the adhesive portion in the adhesive structure in the plane direction is 10 μm or more, the adhesive structure easily has an adhesive strength. The size of the adhesive portion in the adhesive structure in the plane direction is preferably 50,000 μm or less, and more preferably 30,000 μm or less, in view of stress relaxation properties.

The elastic modulus of the adhesive portion is not particularly limited as long as the elastic modulus is higher than the elastic modulus of the low elastic portion and may be appropriately selected according to the purpose, but is preferably 10,000 MPa or less, and more preferably 5,000 MPa or less. The elastic modulus of the adhesive portion is preferably 200 MPa or more in view of the strength of the adhesive portion. In a case where the elastic modulus of the adhesive portion is 10,000 MPa or less, brittle fracture is less likely to occur. The elastic modulus of the adhesive portion can be measured with, for example, a microhardness tester (FISCHERSCOPE HM2000, manufactured by Fisher Instruments Co., Ltd.).

### <Low Elastic Portion and Low Elastic Portion Forming Step>

The low elastic portion is a member patterned having an elastic modulus lower than the elastic modulus of the adhesive portion. The low elastic portion has a function of relaxing thermal stress because of its flexibility. The low elastic portion is suitably formed in the discharging of the low elastic portion forming ink.

The discharging of the low elastic portion forming ink is a step of discharging a low elastic portion forming ink for forming a low elastic portion having an elastic modulus lower than the elastic modulus of the adhesive portion, from a nozzle, to pattern the low elastic portion.

The low elastic portion is formed by being patterned together with the adhesive portion and optionally the thermally conductive portion, and the adhesive portion is not included inside the low elastic portion (that is, not a sea-island structure).

The material forming the low elastic portion is not particularly limited as long as the low elastic portion has an elastic modulus lower than the elastic modulus of the adhesive portion and may be appropriately selected according to the purpose, but preferably contains a resin, and further optionally contains other materials.

### <<Resin>>

The resin forming the low elastic portion is not particularly limited and may be appropriately selected according to the purpose. Examples of the resin include photocurable resins and thermosetting resins. Each of these may be used alone or in combination with others.

In a case where the low elastic portion is formed on an outermost surface of the adhesive structure, it is preferable that a part of the material of the adhesive portion is the same resin as the low elastic portion. In particular, if the optical transparency at the adhesion surface between the adhesive portion and the contact object is not suitable for photocuring through the contact object, the low elastic portion preferably contains at least a thermosetting resin.

Specific examples of the resin include, but are not limited to, a urethane-based resin, an epoxy-based resin, a phenol-based resin, a polyimide-based resin, an ester-based resin, a vinyl-based resin, a silicone-based resin, a styrene-based resin, a cellulose-based resin, an amide-based resin, a (meth)acrylic-based resin, a melamine resin, and a fluoro-based resin. Each of these may be used alone or in combination with others. Among these resins, an epoxy-based resin, a silicone-based resin, and a polyimide-based resin are preferable in view of their good heat resistance, and an epoxy-based resin is more preferable in view of its small cure shrinkage. The resin forming the low elastic portion includes a low elastic resin having an elastic modulus lower than the elastic modulus of the resin forming the adhesive portion by blending the low elastic portion forming ink, which will be described later.

A low elastic portion forming ink containing the monomer component of the resin can be used to form the low elastic portion by applying the low elastic portion forming ink by the above-described patterning before or after patterning the adhesive portion to be subjected to a polymerization reaction.

### <<<Low Elastic Portion Forming Ink>>>

The low elastic portion forming ink may contain the resin, may contain the monomer component of the resin and a polymerization initiator, and may further optionally contain other components. However, it is preferable to contain the monomer component of the resin and the polymerization initiator in view of good performance of patterning.

As for the material of the low elastic portion forming ink, the same material as the adhesive portion forming ink can be used, and accordingly, the description thereof is omitted. Also as for the physical properties, such as the viscosity of the low elastic portion forming ink, other than the elastic modulus, the physical properties are similar to the adhesive portion forming ink, and accordingly, the description thereof is omitted. However, for the low elastic portion forming ink, a commercially available ink can be used such as a low-viscosity epoxy ink and an acrylic ink. Examples of the commercially available ink include, but are not limited to, IJSR4000, IJSR9000 (manufactured by TAIYO INK MFG Co., Ltd.), PR1205, PR1243, PR1258 (manufactured by GOO Chemical Co., Ltd.), SUN-004, SUN-013, SUN-015, C-202, C-400, E635A, E800D (manufactured by Sekisui Chemical Co., Ltd.), and jSVR (manufactured by Dexerials Corporation).

The low elastic portion forming ink allows a cured product to be formed that has a lower elasticity than the adhesive portion and excellent flexibility depending on the type of used ink material and the mixing ratio. Specifically, the type of ink material of the low elastic portion forming ink is preferably an ink mixed with at least one selected from a glycidyl ether type epoxy monomer, a glycidyl amine type epoxy monomer, a (meth)acrylate monomer, an oxetane monomer, a urethane monomer, and the above-described resin or resin particle. In addition, by making the mixing ratio of these materials higher than the mixing ratio of the adhesive portion forming ink, an ink can easily be prepared that forms a cured product having a lower elasticity than the adhesive portion forming ink. The elastic modulus of a cured ink can be confirmed, for example, by measuring the indentation elastic modulus of a film formed and cured on a glass surface with a microhardness meter or the like.

The volume ratio of the low elastic portion to the adhesive structure (low elastic portion/adhesive structure) is not particularly limited and may be appropriately selected according to the purpose, but is preferably from 5 vol % to 90 vol %, and more preferably from 5 vol % to 50 vol %, based on the total volume of the adhesive structure. In a case where the volume ratio of the low elastic portion to the adhesive structure is 5 vol % or more, the stress relaxation properties are good, and in a case where the volume ratio is 90 vol % or less, the adhesiveness of the adhesive portion is good. The low elastic portion is preferably formed at an end portion of the adhesive structure where thermal stress tends to concentrate.

The elastic modulus of the low elastic portion is not particularly limited as long as the elastic modulus is lower than the adhesive portion and may be appropriately selected according to the purpose, but is preferably 70% or less of the elastic modulus of the adhesive portion, and more preferably 50% or less of the elastic modulus of the adhesive portion. In a case where the elastic modulus of the low elastic portion is 70% or less of the elastic modulus of the adhesive portion, the stress relaxation properties are good.

A comparison between the elastic modulus of the low elastic portion and the elastic modulus of the adhesive portion is not particularly limited and may be appropriately selected according to the purpose, but is preferably an elastic modulus ratio [elastic modulus of low elastic portion/elastic modulus of adhesive portion] of 0.01% to 70%, and more preferably 0.02% to 60%.

The elastic modulus of the low elastic portion is not particularly limited as long as the elastic modulus is lower than the elastic modulus of the adhesive portion and may be appropriately selected according to the purpose, but is preferably 3,000 MPa or less, and more preferably 2,000 MPa or less. In a case where the elastic modulus of the low elastic portion is 3,000 MPa or less, the stress relaxation properties are good. The elastic modulus of the low elastic portion can be measured with, for example, a microhardness tester (FISCHERSCOPE HM2000, manufactured by Fisher Instruments Co., Ltd.).

### <Thermally Conductive Portion and Thermally Conductive Portion Forming Step>

The thermally conductive portion is a member formed continuously in the thickness direction of the adhesive structure. The thermally conductive portion has a function of conducting heat in the thickness direction. Therefore, by patterning the thermally conductive portion in the adhesive structure, the thermally conductive property, the heat dissipation property, and the electrically conductive property can be improved between portions on and under the adhesive structure in the thickness direction. Therefore, in a case where the adhesive structure is used for adhesion of a heat-generating component, a cooling component, an electrode, and the like, the adhesive structure preferably has the thermally conductive portion. The thermally conductive portion is suitably formed in the discharging of the thermally conductive portion forming ink.

The discharging of the thermally conductive portion forming ink is a step of discharging a thermally conductive portion forming ink for forming a thermally conductive portion, from a nozzle, to form the thermally conductive portion continuous in the thickness direction of the adhesive structure.

The pattern of the thermally conductive portion in the adhesive structure is not particularly limited as long as the pattern is continuous in the thickness direction of the adhesive structure and may be appropriately selected according to the purpose. Examples of the pattern include, but are not limited to, a pattern surrounded by the adhesive portion, a pattern surrounded by the low elastic portion, and a pattern formed between the adhesive portion and the low elastic portion and surrounded by both the adhesive portion and the low elastic portion. For example, the outer circumferential shape of the thermally conductive portion surrounded by at least one of the adhesive portion and the low elastic portion is not particularly limited and may be appropriately selected according to the purpose. Examples of the shape include, but are not limited to, any combination of shapes including straight lines, circular arcs, and elliptical arcs.

In the adhesive structure, the shape and size of the thermally conductive portion that is exposed on one surface may be the same as or different from the shape and size of the thermally conductive portion that is exposed on the other surface.

### <<Thermally Conductive Portion Forming Ink>>

The material forming the thermally conductive portion is not particularly limited and may be appropriately selected according to the purpose, but the thermally conductive portion preferably contains a thermally conductive material, and further optionally contains other components.

### <<<Thermally Conductive Material>>>

The thermally conductive material is not particularly limited and may be appropriately selected according to the purpose. Examples of the thermally conductive material include, but are not limited to, a metal material, carbon, and a ceramic material. Examples of the metal material include, but are not limited to, silver (Ag), copper (Cu), gold (Au), and aluminum (Al). Examples of the ceramic material include, but are not limited to, silica (SiO₂), aluminum oxide (Al₂O₃), aluminum nitride (AlN), and boron nitride (BN). Each of these may be used alone or in combination with others. Among these, the thermally conductive material is preferably a metal material, and more preferably metal nanoparticles. The metal material can also be used as an electrically conductive material.

The primary average particle diameter of the thermally conductive material in the thermally conductive portion forming ink is not particularly limited and may be appropriately selected according to the purpose, but is preferably from 0.01 μm to 100 μm, and more preferably from 0.3 μm to 10 μm.

The primary average particle diameter of the metal nanoparticles in the thermally conductive portion forming ink is not particularly limited and may be appropriately selected according to the purpose, but is preferably from 0.005 μm to 1 μm, and more preferably from 0.005 μm to 0.2 μm. In a case where the primary average particle diameter of the metal nanoparticles is from 0.005 μm to 1 μm, when the adhesive structure is used for adhesion to a heat-generating component or a cooling component, a highly heat-conductive portion can be formed in which unevenness of a contact surface between the adhesive structure and the heat-generating component or the cooling component is small, and the contact surface is flat and integrated.

The primary average particle diameter of the metal nanoparticles is preferably 200 nm or less in view of the fact that sintering can be performed at a relatively low temperature of about 150° C. In addition, for the metal nanoparticles having a small particle diameter, it is possible to reduce the thickness of the thermally conductive portion and to perform precise patterning by inkjet printing coating with a small-diameter nozzle.

The content of the thermally conductive material in the thermally conductive portion forming ink is not particularly limited and may be appropriately selected according to the purpose, but is preferably from 15 mass % to 100 mass %, and more preferably from 40 mass % to 100 mass %, based on the total mass of the thermally conductive portion forming ink. In a case where the content of the thermally conductive material in the thermally conductive portion forming ink is in the range of 15 mass % to 100 mass %, high thermal conductivity can be obtained.

The thickness of the thermally conductive portion is basically set to be the same as the thickness of the adhesive portion and the low elastic portion, while the area (volume) of the thermally conductive portion is set to an optimum value according to heat dissipation design. In a case where the carbon material is used for coating such as a carbon nanoparticle ink or a graphene ink, the thickness of the thermally conductive portion is preferably from 1 μm to 300 μm. In a case where the ceramic material is used for coating as a ceramic paste in which ceramic particles and resin are mixed, the thickness of the thermally conductive portion is preferably from 1 μm to 500 μm.

The coating method using the carbon ink and the coating method using the ceramic paste are not particularly limited and may be appropriately selected according to the purpose. Examples of the coating method include, but are not limited to, spin coating, casting, micro gravure coating, gravure coating, bar coating, roll coating, wire bar coating, dip coating, slit coating, capillary coating, spray coating, nozzle coating, dispense coating, and various printing methods such as gravure printing, screen printing, flexographic printing, offset printing, reverse printing, and inkjetting.

In a case where the thermally conductive portion forming ink contains a monomer and a polymerization initiator, the ink can be cured by light or heat after coating. In a case where the thermally conductive portion is formed by the inkjetting, a dispersion ink is preferably used such as a metal material, carbon, and a ceramic material. The dispersion ink can be adjusted to have an ink viscosity suitable for inkjet discharge.

The viscosity of the dispersion ink is not particularly limited and may be appropriately selected according to the purpose, but is preferably 5 mPa·s or more and 200 mPa·s or less in view of suitable inkjet discharge.

For the dispersion ink, a dispersion solvent can be used, or a low-viscosity monomer can be used as the dispersion solvent. As the material of the dispersion solvent, the same material as the solvent in the adhesive portion forming ink can be used.

The content of the conductive material in the dispersion ink is not particularly limited and may be appropriately selected according to the purpose, but is preferably 15 mass % or more and 80 mass % or less, based on the total amount of the dispersion ink. In a case where the content of the conductive material in the dispersion ink is 15 mass % or more, it is easy to obtain a thermally conductive effect, and in a case where the content of the conductive material is 80 mass % or less, the viscosity can be reduced, and such an ink can suitably be used for inkjet printing.

### Other Components

The other components are not particularly limited and may be appropriately selected according to a purpose. Examples of the other components include, but are not limited to, a resin, a monomer, a polymerization initiator, a solvent, and a dispersant.

As the resin, the monomer, the polymerization initiator, and the solvent, the similar materials to those of the adhesive portion forming ink can be used, and the preferred aspects are also similar, so that the description thereof will be omitted. The preferred aspects of the solvent and the monomer when used as the dispersion ink are as described above.

### —Dispersant—

The dispersant is not particularly limited and may be appropriately selected according to the purpose. Examples of the dispersant include, but are not limited to, a polyfunctional comb-shaped functional polymer having an ionic group as a main chain and a polyoxyalkylene chain as a graft chain. The ionic group functions as an adsorptive group on the powder surface, and the graft chain controls solubility in the solvent and provides steric repulsion. Specific examples of the dispersant include, but are not limited to, alkylthiol such as dodecanethiol, and a polyvinylpyrrolidone polymer. Each of these may be used alone or in combination with others.

As the dispersant, an appropriately synthesized dispersant may be used, or a commercially available dispersant may be used. Examples of the commercially available dispersant include, but are not limited to, MALIALIM, MALIALIM SC, MALIALIM FA, ESLEAM C, ESLEAM MP, ESLEAM AD, and ESLEAM 221P (manufactured by NOF Corporation).

The content of the other components in the thermally conductive portion forming ink is not particularly limited and may be appropriately selected according to the purpose, but the solid content of the resin, the dispersant, a monomer cured product, and others is preferably 5 mass % or less. As a result, for example, the solid content is removed by being decomposed or gasified during sintering, so that it is possible to form a thermally conductive portion in which the content of the thermally conductive material in the thermally conductive portion is 95 mass % or more.

As the thermally conductive portion forming ink, an appropriately prepared thermally conductive portion forming ink may be used, or a commercially available thermally conductive portion forming ink may be used. In a case where the thermally conductive material contains a metal material, a method of reducing and depositing a metal solution ink can be used instead of the method of using the ink containing the metal material. The metal solution ink is generally known as silver salt inks, and these inks can also be used. Examples of the commercially available thermally conductive portion forming ink include, but are not limited to, those listed in Table 1 below. Each of these may be used alone or in combination with others.

TABLE 1

| | | | Metal | Particle |
|---|---|---|---|---|
| | | | Content | Diameter |
| Metal Species | Manufacturer | Product Name | (wt %) | (nm) |
| Ag Particles | DAICEL | PICOSIL DNS0150I | 50 | 20-30 |
| | DAICEL | PICOSIL DNS0404P | 60-70 | <200 |
| | DAICEL | PICOSIL DNS0215P | 67-78 | <200 |
| | GenesInk | SMART INK Smart Jet I | 20 | <100 |
| | | (S-CS01520) | | |
| | PVnanocell | SICRYS I40DM-106 | 40 | 70 |
| | PVnanocell | SICRYS I50DM-106 | 50 | 80 |
| | PVnanocell | SICRYS I50TM-115 | 50 | 70 |
| | PVnanocell | SICRYS I50TM-119 | 50 | 70 |
| | PVnanocell | SICRYS I50T-13 | 50 | 70 |
| | ULVAC | L-AglTeH | 50-60 | 3-7 |
| | Bando Chemical Industries | FLOWMETAL SW1020 | 40 | 23-33 |
| | Bando Chemical Industries | FLOWMETAL SR7000 | 60 | 30 |
| | Bando Chemical Industries | FLOWMETAL SR7500 | 50 | 30 |
| | Future Ink | F-NANO IJ100GE | 50 | 160 |
| | Future Ink | F-NANO IJ200GE | 37 | 16 |
| | NovaCentrix | METALON JS-A101A | 40 | 30-50 |
| | NovaCentrix | METALON JS-A102A | 40 | 30-50 |
| | NovaCentrix | METALON JS-A191 | 40 | 30-50 |
| | Kishu Giken Kogyo | AGK101, AGK102 | 35 | <200 |
| | Kishu Giken Kogyo | AGK103, AGK104 | 65 | <200 |
| | C-INK | DRYCURE Ag-J 0410B, | 10 | <200 |
| | | 1010B | | |
| | C-INK | DRYCURE Ag-J 0420B, | 20 | <200 |
| | | 1020B | | |
| Silver Salt | Electroninks | EI-710 Ink | 12 | |
| | InkTec | TEC-IJ-010 | 15 | |
| Cu Particles | ISHIHARA CHEMICAL | IJ-02 | 35-45 | <70 |
| | ISHIHARA CHEMICAL | IJ-02A | 35-45 | <70 |
| | PVnanocell | SICRYS IC50DM-7 | 50 wt % | 50 |
| | PVnanocell | SICRYS IC50TM-8 | 50 wt % | 50 |
| | FUKUDA METAL FOIL & | DC-50 | 20 wt % | 50 |
| | POWDER | | | |
| | NovaCentrix | METALON CI-004 | 20 wt % | <200 |
| | NovaCentrix | METALON CI-005 | 26 wt % | <200 |
| Au Particles | C-INK | DRYCURE Au-J 0410B, | 10 wt % | <200 |
| | | 1010B | | |

### Other Steps

The other steps in the method for manufacturing an adhesive structure are not particularly limited and may be appropriately selected according to the purpose. Examples of the other steps include a sintering step.

### <<Sintering Step>>

The sintering step is a step of sintering the metal nanoparticles after the discharging of the thermally conductive portion forming ink. Therefore, the sintering step is suitably performed in a case where the thermally conductive portion forming ink contains metal nanoparticles in the discharging of the thermally conductive portion forming ink.

The method of sintering the metal nanoparticles is not particularly limited and may be appropriately selected from well-known methods. Examples of the methods include, but are not limited to, a method of heating or firing with light. As a result, it is possible to form a thermally conductive portion with high heat conductivity in which the metallic nanoparticles are sintered. In addition, the step of firing the thermally conductive portion forming ink can also serve as heat curing of at least one of the adhesive portion forming ink and the low elastic portion forming ink, for example, a step of bonding the adhesive structure to the contact object.

Next, an adhesive layer as an example of the adhesive structure will be described in detail with reference to the drawings, but the adhesive structure of the present embodiment is not limited to the adhesive layer.

As described above, the adhesive layer includes at least an adhesive portion and a low elastic portion, and may further optionally include a thermally conductive portion.

### Adhesive Layer Embodiment 1

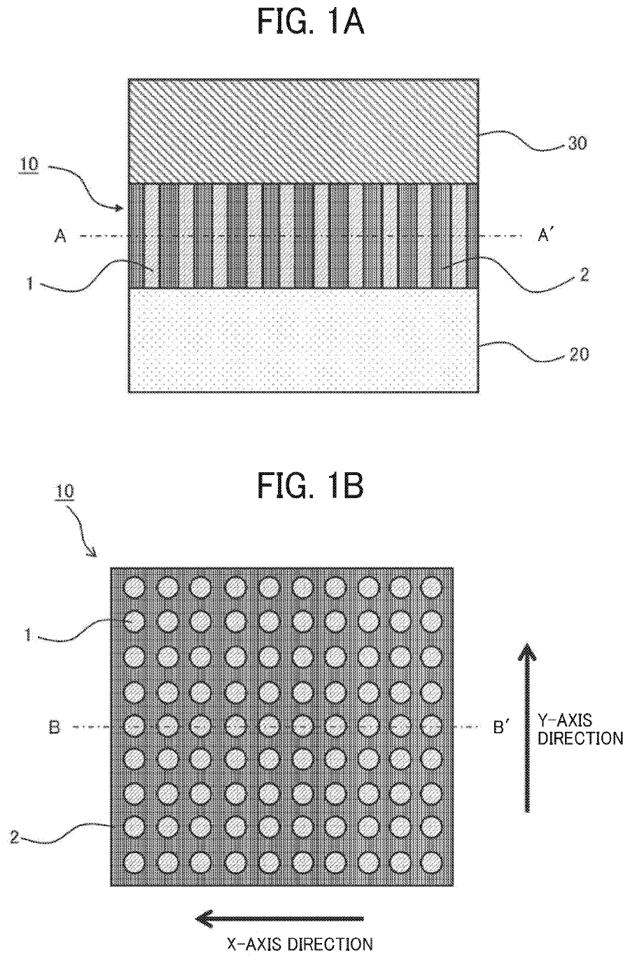

FIGS. 1A and 1B are diagrams illustrating the adhesive structure of the present embodiment (hereinafter sometimes referred to as “Adhesive Layer Embodiment 1”). FIG. 1A is a schematic cross-sectional view of an adhesive layer 10 in the thickness direction (a cross-sectional view in the X direction passing through the center of the Y axis in the plane direction; a cross section taken along B-B′ in FIG. 1B). FIG. 1B is a schematic cross-sectional view of the adhesive layer 10 of FIG. 1A in the plane direction (a cross-sectional view in the X-Y direction passing through the center in the thickness direction; a cross section taken along A-A′ in FIG. 1A). The adhesive layer 10 includes a low elastic portion 2 and a plurality of adhesive portions 1 patterned in the low elastic portion 2. The cross section of the adhesive layer 10 in the plane direction and the outermost surfaces in the plane direction (exposed surfaces, that is, the top view or the bottom view) have the same pattern. In FIG. 1B, the vertical direction is the Y axis and the horizontal direction is the X axis. In FIGS. 1A and 1B, the adhesive layer 10 is formed between a heat-generating component 30 and a substrate 20, but the present embodiment is not limited to this configuration, as exemplified in [Configuration Example 1] to [Configuration Example 6] which will be described later.

### [Conventional Adhesive Layer]

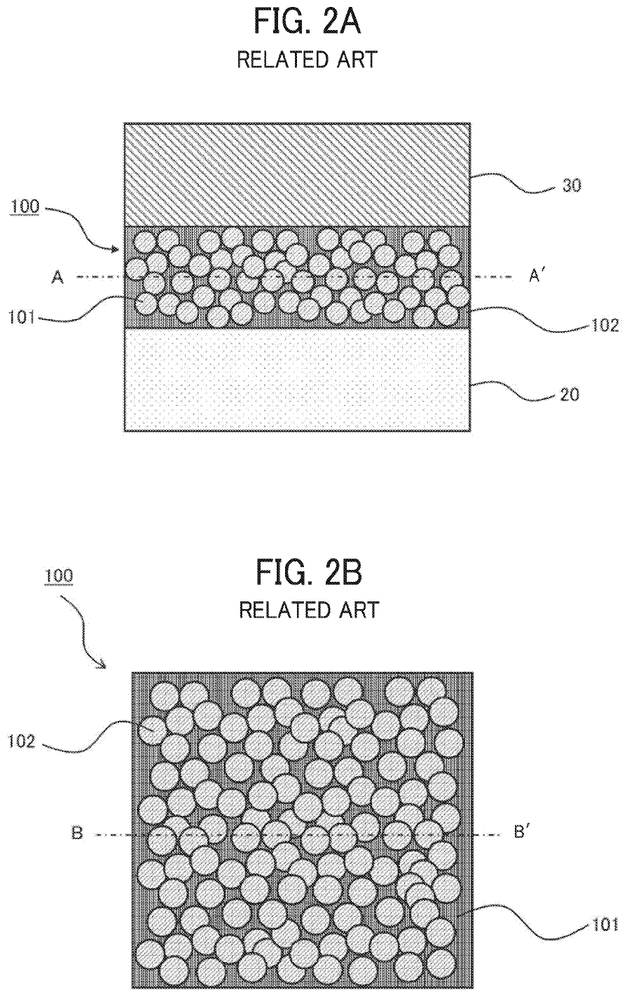

FIGS. 2A and 2B are schematic explanatory diagrams of a conventional adhesive layer having stress relaxation properties (see Japanese Unexamined Patent Application Publication No. 2011-084743). FIG. 2A is a schematic cross-sectional view of the conventional adhesive layer 100 in the thickness direction (a cross section taken along B-B′ in FIG. 2B). FIG. 2B is a schematic cross-sectional view of the adhesive layer 100 of FIG. 2A in the plane direction (a cross section taken along A-A′ in FIG. 2A). The adhesive layer 100 illustrated in FIGS. 2A and 2B has a structure in which adhesive portions 101 are formed as a phase-separated sea-island structure in a low elastic portion 102 (phase-separated sea-island structure). Accordingly, to cause phase separation in the layer in which a low elastic material and an adhesive material are mixed, the adhesive layer is formed substantially uniformly in the thickness direction and the plane direction.

Similarly, an adhesive layer (ACRYSET BP, from Nippon Shokubai Co., Ltd.) has also been proposed in which an elastic rubber (low elastic portion) is mixed with an epoxy resin (adhesive portion). However, the elastic rubber is formed substantially uniformly in the thickness direction and the plane direction, which is inferior in adhesiveness and stress relaxation properties. In particular, in a thin adhesive layer of about 1 μm to 50 μm, there is a problem that it is difficult to obtain a stress relaxation effect because rubber particles having a large particle diameter cannot be uniformly mixed, and the length of the low elastic portion in the plane direction cannot be 10 μm or more. Also for the phase-separated sea-island structure to be formed, it is difficult to control its size.

In the adhesive structure of the present embodiment, the patterning of the adhesive portion 1 and the low elastic portion 2 may be appropriately adjusted to obtain the adhesiveness and stress relaxation properties preferable for the adhesive layer 10. For example, as illustrated in FIGS. 3A to 3I and FIGS. 4A to 4H, it is possible to set various patterns such as dot, line, ring, lattice, and radial patterns. In particular, it is preferable to form a large amount of the low elastic portion 2 in a portion where thermal stress (strain) is large, and to form a large amount of the adhesive portion 1 on the adhesion surface. FIGS. 3A to 3I are illustrations of variations in patterning of the adhesive structure in the thickness direction, and FIGS. 4A to 4H are illustrations of variations in patterning of the adhesive structure in the plane direction.

### Adhesive Layer Embodiment 2

FIG. 3A is a schematic cross-sectional view in the thickness direction, of another adhesive structure of the present embodiment (hereinafter sometimes referred to as “Adhesive Layer Embodiment 2”). This differs from Adhesive Layer Embodiment 1 in that a large amount of the adhesive portion 1 is formed on the contact surface of the heat-generating component 30. In a case where the substrate 20 and the heat-generating component 30 have different linear thermal expansion coefficients and the thermal expansion of the substrate 20 is large, increasing the amount of the low elastic portion 2 on the substrate 20 side makes it easier for the substrate 20 to expand and contract, leading to efficient stress relaxation. On the other hand, increasing the amount of the adhesive portion 1 on the contact surface with the heat-generating component 30, which is hotter, makes it possible to improve the adhesiveness.

### Adhesive Layer Embodiment 3

FIG. 3B is a schematic cross-sectional view in the thickness direction, of another adhesive structure of the present embodiment (hereinafter sometimes referred to as “Adhesive Layer Embodiment 3”). This differs from Adhesive Layer Embodiment 2 in that the low elastic portion 2 is formed as a trapezoid with a large adhesion area on the contact surface with the substrate 20. By changing the ratio between the adhesive portion 1 and the low elastic portion 2 in the thickness direction, the adhesiveness and stress relaxation performance can easily be adjusted.

### Adhesive Layer Embodiment 4

FIG. 3C is a schematic cross-sectional view in the thickness direction, of another adhesive structure of the present embodiment (hereinafter sometimes referred to as “Adhesive Layer Embodiment 4”). This differs from Adhesive Layer Embodiment 3 in that the amount of the low elastic portion 2 is larger in the outer circumferential portion in the plane direction (regions near the exposed portions in the thickness direction). Strain generally increases toward the outer circumferential portion. Accordingly, by increasing the amount of the low elastic portion in the outer circumferential portion, the strain can efficiently be relaxed.

### Adhesive Layer Embodiment 5

FIG. 3D is a schematic cross-sectional view in the thickness direction, of another adhesive structure of the present embodiment (hereinafter sometimes referred to as “Adhesive Layer Embodiment 5”). This differs from Adhesive Layer Embodiment 2 in that the low elastic portion 2 is not formed on both contact surfaces in the plane direction of the adhesive layer 10 (the exposed portions at the outermost surfaces in the plane direction). By forming the low elastic portion 2 inside the adhesive layer 10, adhesiveness on the contact surfaces and stress relaxation properties inside the adhesive layer 10 can be efficiently obtained.

### Adhesive Layer Embodiment 6

FIG. 3E is a schematic cross-sectional view in the thickness direction, of another adhesive structure of the present embodiment (hereinafter sometimes referred to as “Adhesive Layer Embodiment 6”). This differs from Adhesive Layer Embodiment 5 in that the low elastic portion 2 is patterned in the film thickness direction of the adhesive layer 10. By patterning the low elastic portion 2 also in the thickness direction, it is possible to finely adjust the adhesiveness and stress relaxation properties. Stress generally causes warpage in the adhesive layer 10. However, since the stress at a central portion of the adhesive layer 10 in the thickness direction tends to be small, increasing the amount of the adhesive portion 1 in the central portion in the thickness direction (that is, reducing the amount of the low elastic portion 2) makes it possible to achieve both effective stress relaxation and adhesiveness according to the stress.

### Adhesive Layer Embodiment 7

FIG. 3F is a schematic cross-sectional view in the thickness direction, of another adhesive structure of the present embodiment (hereinafter sometimes referred to as “Adhesive Layer Embodiment 7”). This differs from Adhesive Layer Embodiment 6 in that low elastic portions 2 are randomly arranged in the thickness direction of the adhesive layer 10, and a larger number of the low elastic portions 2 are distributed on both end sides (exposed portion sides in the plane direction) of the adhesive layer 10.

### Adhesive Layer Embodiment 8

FIG. 3G is a schematic cross-sectional view in the thickness direction, of another adhesive structure of the present embodiment (hereinafter sometimes referred to as “Adhesive Layer Embodiment 8”). This differs from Adhesive Layer Embodiment 3 in that the thermally conductive portion 3 continuous in the thickness direction of the adhesive layer 10 is formed between the low elastic portions 2 on the contact surface with the substrate 20.

### Adhesive Layer Embodiment 9

FIG. 3H is a schematic cross-sectional view in the thickness direction, of another adhesive structure of the present embodiment (hereinafter sometimes referred to as “Adhesive Layer Embodiment 9”). This differs from Adhesive Layer Embodiment 3 in that the thermally conductive portion 3 continuous in the thickness direction of the adhesive layer 10 is formed between one of adjacent adhesive portions 1 and the other adhesive portion 1 on the contact surface with the substrate 20.

### Adhesive Layer Embodiment 10

FIG. 3I is a schematic cross-sectional view in the thickness direction, of another adhesive structure of the present embodiment (hereinafter sometimes referred to as “Adhesive Layer Embodiment 10”). This differs from Adhesive Layer Embodiment 9 in that the low elastic portion 2 is formed inside the adhesive layer 10 in the thickness direction.

In Adhesive Layer Embodiments 8 to 10, by forming the thermally conductive portion 3, the thermal conductivity of the adhesive layer 10 in the thickness direction can be improved, and accordingly, the heat dissipation effect can be imparted. In a case where the thermally conductive layer 3 also serves as an electrically conductive layer, an electrically conductive effect can be imparted.

FIG. 4A is a schematic top view in the plane direction, of an adhesive structure according to the present embodiment in which the low elastic portion 2 is radially patterned in the plane direction. FIG. 4B is a schematic top view in the plane direction, of another adhesive structure in which the low elastic portion 2 is patterned in a ring shape in the plane direction. FIG. 4C is a schematic top view in the plane direction, of another adhesive structure in which the low elastic portion 2 is patterned in a grid shape in the plane direction. FIG. 4D is a schematic top view in the plane direction, of another adhesive structure in which the low elastic portion 2 is patterned on the outer circumferential portion of the adhesive layer where stress tends to concentrate in the plane direction. FIG. 4E is a schematic top view in the plane direction, of another adhesive structure in which a crisscross lattice-like low elastic portion 2 is further patterned in the plane direction in the inside of FIG. 4D. The patterning in FIGS. 4A, 4B, 4C, 4D, and 4E may have the same pattern on the exposed surface (top view) and a cross section in the plane direction, and may have different patterns on the exposed surface (top view) and a cross section in the plane direction.

FIGS. 4F, 4G, and 4H are schematic top views in the plane direction, of other adhesive structures that are applied to the case where contacts for wire bonding are formed on a surface of a heat-generating component (for example, a die). FIGS. 4F and 4G are illustrations in which the low elastic portion 2 is formed at the upper and lower ends of the drawings, and a wire bonding contact portion 4 penetrating the low elastic portion 2 is formed, so that strain due to wire-bonding formation is effectively relaxed. Thus, according to the adhesive structure, the stress relaxation performance can be improved by elastic adjustment patterning in a portion where strain is likely to occur (for example, a contact portion with a wiring portion, for example, for wire bonding or a flip chip). In addition, using the low elastic portion forming ink enables patterning coating with excellent filling properties, and makes it possible to suppress the generation of bubbles and voids, which may be starting points at which the adhesive structure peels off. In this case, it is effective to perform coating by inkjetting. The inkjetting makes it possible to form an adhesive structure into a thin film in any pattern with excellent uniformity. In addition, it is possible to perform patterning coating while avoiding a wiring portion, for example, for wire bonding and a flip chip.

FIG. 4H is an illustration in which the adhesive layer 10 is patterned such that no adhesive layer 10 is formed around the wire bonding contact portion 4 for the purpose of the similar effect.

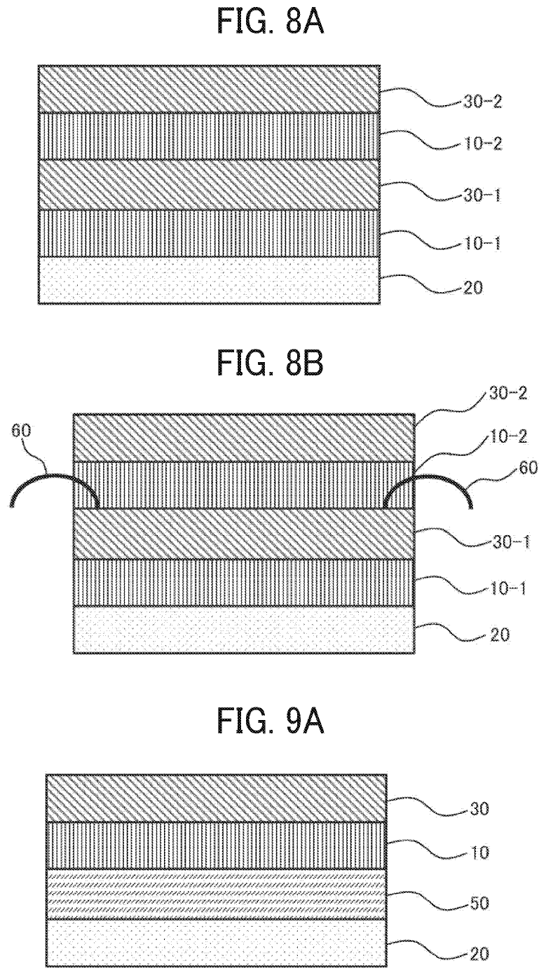

The arrangement of FIGS. 4F, 4G, and 4H is effective for the case where contacts for wire bonding are formed on a heat-generating component in configurations in which an adhesive layer is formed between heat-generating components (semiconductors: dies) as in Configuration Example 3 of FIG. 7B and Configuration Example 4 of FIG. 8B, which will be described later. The patterning in FIGS. 4F, 4G, and 4H may have the same pattern on the exposed surface and in the thickness direction, or may have different patterns on the exposed surface and in the thickness direction.

### (Adhesive Layer for Transfer)

An adhesive layer for transfer of the present embodiment has the adhesive structure of the present embodiment as a layered adhesive structure formed on a temporary support body.

The adhesive structure of the present embodiment is as described in the heading “Adhesive Structure and Method for Manufacturing Adhesive Structure), and accordingly, the details are omitted.

### <Temporary Support Body>

The temporary support body is not particularly limited as long as the adhesive structure can be manufactured on the surface of the temporary support body and the temporary support body does not affect the adhesive portion, the low elastic portion, and the thermally conductive portion, which are patterned in the adhesive structure, and optionally, other members. As the temporary support body, a well-known release sheet can be used.

The release sheet is not particularly limited and may be appropriately selected according to the purpose. Examples of the release sheet include, but are not limited to, paper such as kraft paper, glassine paper, and woodfree paper; a resin film such as polypropylene (biaxially oriented polypropylene (OPP), cast polypropylene (CPP)) and polyethylene terephthalate (PET); laminated paper obtained by laminating the above paper and the above resin film; and a product in which one or both sides of a sheet of the above paper that has been subjected to filling treatment with, for example, clay or polyvinyl alcohol have been subjected to peeling treatment with, for example, a silicone-based resin. Each of these may be used alone or in combination with others.

The method for forming the layered adhesive structure on the temporary support body is not particularly limited. The layered adhesive structure can be formed in the same manner as in the above-described method for manufacturing the adhesive structure, except that the contact object is replaced with the support body.

The adhesive layer for transfer facilitates storage and transportation of the adhesive structure and is excellent in handleability. The adhesive layer for transfer is also advantageous in that the adhesive structure can easily be formed on a contact object in a manner that the adhesive layer for transfer is stuck to the contact object and the support body is peeled off even in a case where the adhesive structure cannot be directly formed on the contact object.

### (Electronic Component and Method for Manufacturing Electronic Component)

An electronic component of the present embodiment has at least the adhesive structure of the present embodiment, and further optionally includes other members. The adhesive structure of the present embodiment is as described in the heading “Adhesive Structure and Method for Manufacturing Adhesive Structure), and accordingly, the details are omitted.

A method for manufacturing an electronic component of the present embodiment includes fixing a component by using the adhesive structure of the present embodiment, and further optionally includes other steps.

The method for fixing the component by using the adhesive structure is not particularly limited and may be appropriately selected according to the configuration of the adhesive structure. Examples of the method include, but are not limited to, photocuring and heat curing.

### First Component and Second Component

The electronic component preferably includes a first component and a second component that is fixed by the adhesive structure.

The difference in linear thermal expansion coefficient between the first component and the second component is not particularly limited and may be appropriately selected according to the purpose, but is preferably 20 ppm/K or less, and more preferably 10 ppm/K or less. In a case where the difference in linear thermal expansion coefficient is 20 ppm/K or less, the adhesive structure has little warpage. It is preferable that the difference in linear thermal expansion coefficient between the first component and the second component is as low as possible, and the lower limit of the difference is not particularly limited. Since the electronic component of the present embodiment includes the adhesive structure of the present embodiment, even if the difference in linear thermal expansion coefficient is high, the electronic component is excellent in adhesiveness and stress relaxation properties, and can thus prevent poor adhesion and poor connection. In particular, the low elastic portion in the adhesive structure can prevent deformation caused by the difference in linear thermal expansion coefficient between the first component and the second component.

The difference in linear thermal expansion coefficient between the first component and the second component can be measured by a thermomechanical analysis device (for example, thermomechanical analysis (TMA)).

The first component and the second component are not particularly limited and may be appropriately selected according to the type of the target electronic component. Examples of the components include, but are not limited to, an aspect in which the first component is a heat-generating component and the second component is a substrate, and an aspect in which the first component is a cooling component and the second component is a substrate.

The heat-generating component is not particularly limited and may be appropriately selected according to the type of the target electronic component. Examples of the heat-generating component include, but are not limited to, a semiconductor (die), a semiconductor package, a battery, an LED, a capacitor, a resistor, and a diode. Among these, the heat-generating component is preferably a semiconductor (IC chip), which is preferable to have reliability of heat resistance in adhesion and connection of mounted circuits at increased temperatures due to recent high integration and high speed.

In the electronic component, the adhesive structure is preferably at least one of a die bonding layer, a heat dissipation layer, and a resist. The adhesive structure functions suitably as a die bonding layer because of including the adhesive portion. Moreover, in a case of including the thermally conductive portion, the adhesive structure functions suitably as a heat-dissipating layer.

The electronic component may include an intermediate layer such as a surface treatment layer between the adhesive structure and the first component or the second component.

The surface treatment layer is formed as a layer that adjusts wettability or surface energy of the surface of the formed adhesive structure, and is formed as a resin film having a hydrophilic group or a hydrophobic group on the surface.

The material of the surface treatment layer is not particularly limited and may be appropriately selected according to the purpose. Examples of the material to be used include, but are not limited to, a material having, for example, a carboxyl group, an amino group, a keto group, an OH group, a fluorine group, or a silanol group in a resin structure. The material may be mixed with inorganic particles such as ceramics, metals, and carbon. These can be the same as those contained in the thermally conductive portion forming ink.

The thickness of the surface treatment layer is not particularly limited and may be appropriately selected according to the purpose, but is preferably from 0.5 μm to 10 μm.

The method of forming the surface treatment layer is not particularly limited and may be appropriately selected according to the purpose. For example, the surface treatment layer can be formed by coating a mixture of an organic monomer material having at least a reactive group and a resin material or an inorganic material in which an initiator is mixed, and then performing curing treatment such as UV irradiation, heat treatment, and dehydration treatment.

The coating method is not particularly limited and may be appropriately selected according to the purpose. Examples of the method of coating metal nanoparticle ink as the conductive portion 2 include, but not limited to, spin coating, casting, micro gravure coating, gravure coating, bar coating, roll coating, wire bar coating, dip coating, slit coating, capillary coating, spray coating, nozzle coating, dispense coating, and various printing methods such as gravure printing, screen printing, flexographic printing, offset printing, reverse printing, and inkjet printing.

The electronic component may be formed with a solder resist using, for example, a commercially available photocurable ink or thermosetting ink. Examples of the commercially available solder resist include, but are not limited to, PSR-4000 G24K/CA-40 G24, PSR-4000 BL01/CA-40 G24, PSR-4000 GEC50K1/CA-40 G50, PSR-4000 EG23/CA-40 G23K, PSR-4000 EG30/CA-40 G23K, IJSR4000, IJSR9000 (manufactured by Taiyo Ink Co., Ltd.), PSR-310, PSR-400B, PSR-500B, PR1205, PR1243, and PR1258 (manufactured by GOO Chemical Co., Ltd.).

A usage of the adhesive structure in the electronic component will be described below in detail with reference to the drawings, but the usage of the electronic component and the adhesive structure of the present embodiment is not limited to the usage described below.

### Configuration Example 1

FIG. 5 is a schematic cross-sectional view of an electronic component using the adhesive structure of the present embodiment (hereinafter sometimes referred to as “Configuration Example 1”). In FIG. 5, the heat-generating component 30 and the substrate 20 are adhered by the adhesive layer 10 as the adhesive structure of the present embodiment.

Specific examples of the heat-generating component 30 as the electronic component include, but are not limited to, a semiconductor (die), a semiconductor package, a battery, an LED, a capacitor, a resistor, and a diode.

The adhesive layer 10 relaxes stress caused by the difference in linear thermal expansion coefficient between the heat-generating component 30 and the substrate 20, and maintains the adhesiveness even when the temperature changes.

### Configuration Example 2

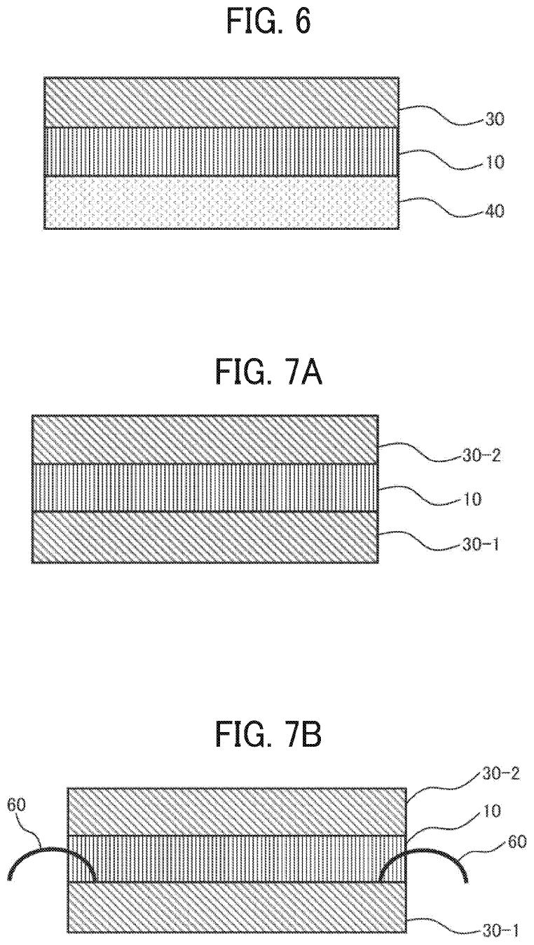

FIG. 6 is a schematic cross-sectional view of another electronic component using the adhesive structure of the present embodiment (hereinafter sometimes referred to as “Configuration Example 2”). FIG. 6 differs from Configuration Example 1 in that a cooling component 40 is adhered in place of the substrate 20 in Configuration Example 1.

The cooling component 40 is a component for cooling the heat of the heat-generating component 30 by, for example, air cooling, liquid cooling, phase change cooling, or thermoelectric cooling. Specific examples of the cooling component 40 include, but are not limited to, a heat sink, a heat pipe, a microchannel, a Peltier element, a heat dissipation sheet, and a heat spreader.

### Configuration Example 3

FIGS. 7A and 7B are schematic cross-sectional views of other electronic components using the adhesive structure of the present embodiment (hereinafter sometimes referred to as “Configuration Example 3”). FIGS. 7A and 7B differ from Configuration Example 1 in that a heat-generating component 30-2 is adhered to another heat-generating component 30-1 via the adhesive layer 10. The configurations of FIGS. 7A and 7B are effective for reducing and uniformizing the temperature difference between the heat-generating components 30-1 and 30-2 in the case where the heat-generating components 30-1 and 30-2 are laminated. FIG. 7B is an example in which each heat-generating component is a semiconductor (die) and the heat-generating component 30-1 has a wiring portion 60 on its top surface. Specifically, FIG. 7B is an example of wire bonding from the top surface of the heat-generating component 30-1.

### Configuration Example 4

FIGS. 8A and 8B are schematic cross-sectional of other electronic components using the adhesive structure of the present embodiment (hereinafter sometimes referred to as “Configuration Example 4”). FIGS. 8A and 8B differ from Configuration Example 1 in that the other heat-generating component 30-2 is adhered to the heat-generating component 30-1 via another adhesive layer 10-2 and the heat-generating component 30-1 is adhered to the substrate 20 via an adhesive layer 10-1. In FIG. 8B, each heat-generating component is a semiconductor (die) and the heat-generating component 30-1 has a wiring portion 60 on its top surface. Specifically, FIG. 8B is an example of wire bonding from the top surface of the heat-generating component 30-1.

The patterns of the adhesive portions and the low elastic portions in the adhesive layers 10-1 and 10-2, and optionally, the pattern of the thermally conductive portion, and the thicknesses of the adhesive layers 10-1 and 10-2 can be selected independently as appropriate. In other words, the adhesive portions, the low elastic portions, and the thermally conductive portions of the adhesive layers 10-1 and 10-2 may have the same pattern or may have different patterns. The thicknesses of the adhesive layers 10-1 and 10-2 may be the same or different. Among these, it is preferable that in view of adhesive strength and stress relaxation properties, the patterns of the adhesive portions, the low elastic portions, and the thermally conductive portions in the adhesive layers 10-1 and 10-2 are different patterns, and the adhesive layers 10-1 and 10-2 are selected to have different thicknesses.

### Configuration Example 5

FIGS. 9A and 9B are schematic cross-sectional views of other electronic components using the adhesive structure of the present embodiment (hereinafter sometimes referred to as “Configuration Example 5”). FIG. 9A differs from Configuration Example 1 in that an intermediate layer 50 is formed between the substrate 20 and the adhesive layer 10. FIG. 9B differs from Configuration Example 1 in that an intermediate layer 50 is formed between the heat-generating component 30 and the adhesive layer 10.

The intermediate layer 50 may be formed at least either one of between the adhesive layer 10 and the substrate 20 or between the adhesive layer 10 and the heat-generating component 30. The intermediate layer 50 is not particularly limited and may be appropriately selected according to the purpose. Examples of the intermediate layer 50 include, but are not limited to, a heat diffusion portion that diffuses heat in the plane direction and a surface treatment portion that improves adhesion.

### Configuration Example 6

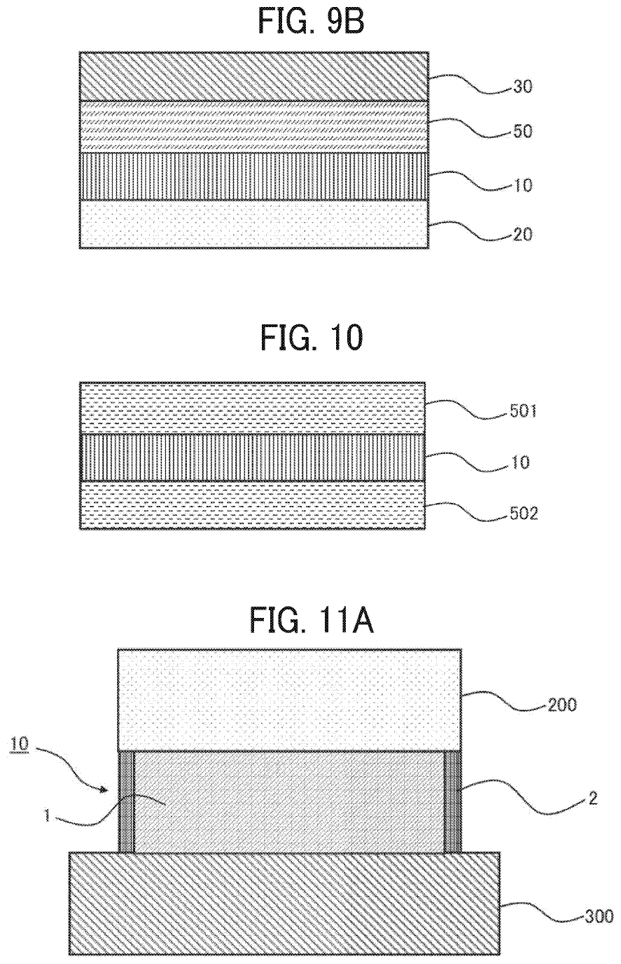

FIG. 10 is a schematic cross-sectional view of another electronic component using the adhesive structure of the present embodiment (hereinafter sometimes referred to as “Configuration Example 6”). FIG. 10 differs from Configuration Example 1 in that the adhesive layer 10 is formed between electrodes 501 and 502. Configuration Example 6 is effective for the case where electrodes are insulated from each other or the case where conduction is performed between electrodes.

A commonly-used material for electrodes can be used for the electrodes 501 and 502. Specific examples of the material for electrodes include, but are not limited to, silver (Ag), copper (Cu), gold (Au), aluminum (Al), nickel (Ni), tin (Sn), platinum (Pb), and carbon materials. Each of these may be used alone or in combination with others. The electrodes may be divided and patterned as wiring patterns.

The method for manufacturing the electronic component is not particularly limited as long as the method includes fixing a component by using the adhesive structure, and may be appropriately selected according to the purpose. The component may be fixed using the adhesive layer for transfer of the present embodiment, or the adhesive structure may be formed directly on the component as a contact object.

In a case where the adhesive structure is a resist in the electronic component, a preferable method includes: discharging an adhesive portion forming ink for forming an adhesive portion to adhere to a contact object, from a nozzle, onto a substrate at a position corresponding to a first region that is an edge of a resulting resist pattern, to dispose the adhesive portion and to form a first resist layer; discharging a low elastic portion forming ink for forming a low elastic portion having an elastic modulus lower than an elastic modulus of the adhesive portion, from a nozzle, onto the substrate at a position corresponding to a second region that is different from the first region, to pattern and dispose the low elastic portion and to form a second resist layer; and curing the first resist layer and the second resist layer to form resist patterns, wherein the discharging of the adhesive portion forming ink and the discharging of the low elastic portion forming ink include simultaneously disposing the adhesive portion forming ink and the low elastic portion forming ink on the substrate, and forming a resist pattern in which a portion corresponding to the first region of the resist pattern formed by the adhesive portion forming ink and a portion corresponding to the second region of the resist pattern formed by the low elastic portion forming ink are continuous.

The discharge of the adhesive portion forming ink, the discharge of the low elastic portion forming ink, the patterning of the low elastic portion forming ink, and the like, to form a resist can be performed using the same methods as those in the method for manufacturing an adhesive structure of the present embodiment.

### EXAMPLES

Specific examples of the present embodiment will be described below with reference to Preparation Examples, Examples, and Comparative Examples, but the present embodiment is not limited to these Preparation Examples and Examples. In the following Preparation Examples, Examples, and Comparative Examples, the term “parts” refers to “parts by mass” and the term “%” refers to “mass %” unless otherwise specified.

Materials listed in Table 2 below were prepared as the materials for the adhesive portion forming ink and the low elastic portion forming ink in the following Preparation Examples. Table 2 below also includes the viscosity of each material.

TABLE 2

| | | | Viscosity |
|---|---|---|---|
| Material | Trade Name | Structural Formula | [mPa · s] |
| Epoxy Monomer | EPOCHALIC THI-DE | Structural Formula 1 | 20 |
| | CEL8010 | Structural Formula 8 | 60 |
| | OCR-EP | Structural Formula 23 | 6 |
| | PETG | Structural Formula 24 | 310 |
| | TETRAD-X | Structural Formula 34 | 1600-2500 |
| Oxetane Monomer | ARON OXETANE OXT-221 | Structural Formula 30 | 9-14 |
| | ARON OXETANE OXT-221 | Structural Formula 27 | 3-6 |
| Acrylic Monomer | OXE-10 | Structural Formula 33 | 4.3 |
| | A-DPH | — | 7500 |
| Thermosetting | SAN-AID SI-150 | — | Solid |
| Initiator | | | |
| Photocuring | IRGACURE TPO | — | Solid |
| Initiator | | | |
| Acrylic Ink | SUN-013 | — | 19 |

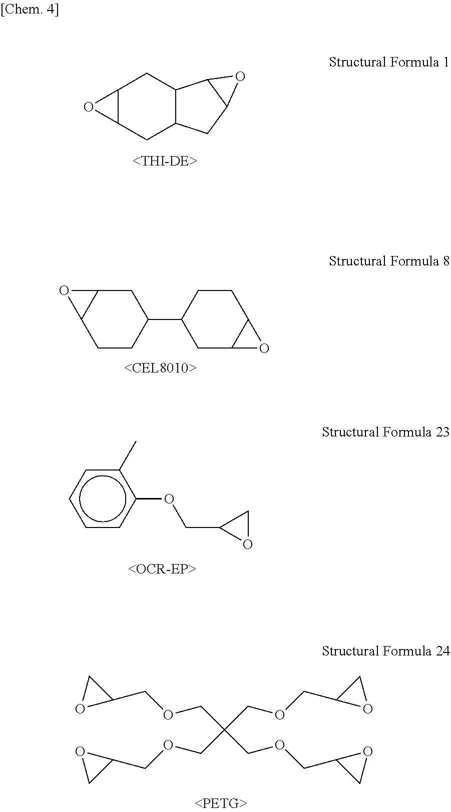

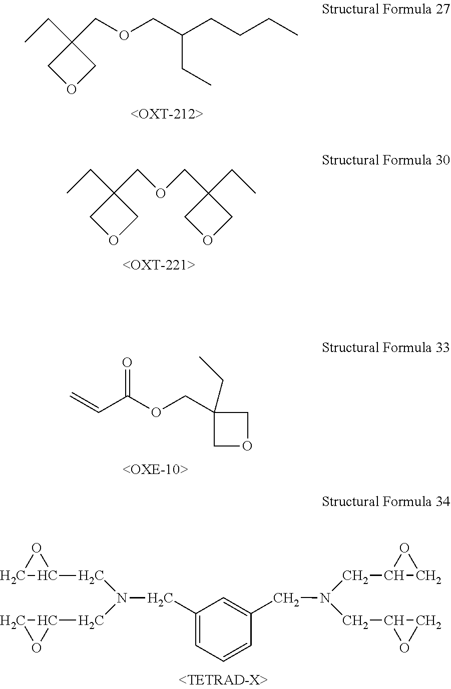

### <Viscosity Measurement Method>

In the following Preparation Examples, a cone rotor (1°34′×R24) in a cone and plate type rotational viscometer (VISCOMETER TVE-22L, manufactured by Toki Sangyo Co., Ltd.) was used to measure the viscosity of each ink at a rotation speed of 10 rpm under constant temperature circulating water set to 25° C. To adjust the temperature of the circulating water, a circulating constant temperature bath (for example, VISCOMATE VM-150III, manufactured by Toki Sangyo Co., Ltd.) was used.

### Preparation Example 1-1: Preparation of Adhesive Portion Forming Ink A-1

60 parts of glycidyl ether type monofunctional epoxy monomer OCR-EP (manufactured by Yokkaichi Chemical Co., Ltd.), 20 parts of glycidyl ether type tetrafunctional epoxy monomer PETG (manufactured by Showa Denko K.K.), 20 parts of glycidyl amine type tetrafunctional epoxy monomer TETRAD-X (manufactured by Mitsubishi Gas Chemical Company, Inc.), and 1 part of thermal polymerization initiator (SAN-AID SI-150L) were mixed to prepare a thermosetting [adhesive portion forming ink A-1]. The viscosity of the [adhesive portion forming ink A-1] at 25° C. was 22.9 mPa-s, which was suitable for inkjet printing.

### Preparation Example 1-2: Preparation of Adhesive Portion Forming Ink A-2

100 parts of alicyclic epoxy monomer (EPOCHALIC THI-DE, manufactured by ENEOS Corporation) and 1 part of thermal polymerization initiator (SAN-AID SI-150L) were mixed to prepare a thermosetting [adhesion portion forming ink A-2]. The viscosity of the [adhesion portion forming ink A-2] at 25° C. was 19.3 mPa·s, which was suitable for inkjet printing.

### Preparation Example 1-3: Preparation of Adhesive Portion Forming Ink A-3

36 parts of alicyclic epoxy monomer (EPOCHALIC THI-DE, manufactured by ENEOS Corporation), 12 parts of glycidylamine type tetrafunctional epoxy monomer TETRAD-X (manufactured by Mitsubishi Gas Chemical Company, Inc.), 32 parts of oxetane monomer (ARON OXETANE OXT-221, manufactured by Toagosei Co., Ltd.), 19 parts of oxetane acrylic monomer (OXE-10, manufactured by Osaka Organic Chemical Industry Ltd.), 2 parts of polyfunctional dipentaerythritol polyacrylic monomer (A-DPH, manufactured by Shin-Nakamura Chemical Co., Ltd.), 0.1 part of photopolymerization initiator (IRGACURE TPO, manufactured by IGM Resins B.V.), and 0.8 part of thermal polymerization initiator (SAN-AID SI-150L, manufactured by Sanshin Chemical Industry Co., Ltd.) were mixed to prepare a photocurable, thermosetting [adhesion portion forming ink A-3]. The viscosity of the [adhesion portion forming ink A-3] at 25° C. was 32.0 mPa-s, which was suitable for inkjet printing.

### Preparation Example 2-1: Preparation of Low Elastic Portion Forming Ink B-2

50 parts of alicyclic epoxy monomer (CEL8010P, manufactured by Daicel Corporation), 50 parts of oxetane monomer (ARON OXETANE OXT-212, manufactured by Toagosei Co., Ltd.), and 1.0 part of thermal polymerization initiator (SAN-AID SI-150L, Sanshin Chemical Industry Co., Ltd.) were mixed to prepare a thermosetting [low elastic portion forming ink B-2]. The viscosity of the [low elastic portion forming ink B-2] at 25° C. was 28.1 mPa·s, which was suitable for inkjet printing.

### <Measurement of Indentation Elastic Modulus of Cured Film>

The indentation elastic moduli of cured products, in which the [adhesive portion forming ink A-1] to [adhesive portion forming ink A-3] obtained in Preparation Examples 1-1 to 1-3, SUB-013 (manufactured by Sekisui Chemical Co., Ltd.) prepared as the low elastic portion forming ink B-1, and the [low elastic portion forming ink B-2] obtained in Preparation Example 2-1 were cured, were measured by the following method.

The [adhesive portion forming ink A-1] to [adhesive portion forming ink A-3] obtained in Preparation Examples 1-1 to 1-3, SUB-013 (manufactured by Sekisui Chemical Co., Ltd.) prepared as the low elastic portion forming ink B-1, and the [low elastic portion forming ink B-2] obtained in Preparation Example 2-1 were each inkjet-printed onto the surface of a glass with a thickness of 10 mm, then heated at 100° C. for 2 hours, and further subjected to heat curing treatment at 200° C. for 1 hour to manufacture a cured film with a thickness of 15 μm. The photocurable, thermosetting ink was subjected to pre-photocuring with a UV LED (365 nm) using a Honle LED Cube 100 (manufactured by Honle UV Technology) before heat curing, and then heat-cured. As an inkjet device, a single-nozzle ultra-fine inkjet device (manufactured by Cluster Technology Co., Ltd.) with a nozzle hole diameter of 25 μm was used.

The indentation elastic moduli of the cured films prepared by the above method were measured with a microhardness tester (FISCHERSCOPE HM2000, manufactured by Fisher Instruments Co., Ltd.) under the following measurement conditions. Tables 3-1 and 3-2 below indicate the measurement results of the indentation elastic moduli of the ink cured films.

### [Measurement Conditions]

Indenter: Vickers indenter
Maximum load: 10 mN
Maximum indentation depth: 1 μm
Loading (unloading) time: 40 sec

TABLE 3-1

| | | Preparation | Preparation | Preparation |
|---|---|---|---|---|
| | | Example | Example | Example |
| | | 1-1 | 1-2 | 1-3 |
| | | Adhesion | Adhesion | Adhesion |
| Formulation | | Portion Forming | Portion Forming | Portion Forming |
| [Mass Part] | | Ink A-1 | Ink A-2 | Ink A-3 |
| Epoxy | EPOCHALIC THI-DE | — | 100 | 36 |
| Monomer | CEL8010 | — | — | — |
| | OCR-EP | 60 | — | — |
| | PETG | 20 | — | — |
| | TETRAD-X | 20 | — | 12 |
| Oxetane | ARON OXETANE OXT-221 | — | — | 32 |
| Monomer | ARON OXETANE OXT-221 | — | — | — |
| Acrylic | OXE-10 | — | — | 19 |
| Monomer | A-DPH | — | — | 2 |
| Thermosetting | SAN-AID | 1.0 | 1.0 | 0.8 |
| Initiator | SI-150 | | | |
| Photocuring | IRGACURE TPO | — | — | 1.0 |
| Initiator | | | | |
| Ink | Viscosity [mPa · s] (25° C.) | 22.9 | 19.3 | 32 |
| Characteristics | | | | |
| Thermosetting | Indentation Elastic Modulus | 4,666 | 7,200 | 3,150 |
| Product | [Mpa] | | | |
| Characteristics | | | | |

TABLE 3-2

| | | | Preparation |
|---|---|---|---|
| | | | Example |
| | | SUN-013 | 2-1 |
| | | Low Elastic | Low Elastic |
| Formulation | | Portion Forming | Portion Forming |
| [Mass Part] | | Ink B-1 | Ink B-2 |
| Epoxy | EPOCHALIC THI-DE | — | — |
| Monomer | CEL8010 | — | 50 |
| | OCR-EP | — | — |
| | PETG | — | — |
| | TETRAD-X | — | — |
| Oxetane | ARON OXETANE OXT-221 | — | — |
| Monomer | ARON OXETANE OXT-221 | — | — |
| Acrylic | OXE-10 | — | — |
| Monomer | A-DPH | — | — |
| Thermosetting | SAN-AID | — | 1.0 |
| Initiator | SI-150 | | |
| Photocuring | IRGACURE TPO | — | — |
| Initiator | | | |
| Acrylic Ink | SUN-013 | 100 | — |
| Ink | Viscosity [mPa · s] (25° C.) | 19.0 | 28.1 |
| Characteristics | | | |
| Thermosetting | Indentation Elastic Modulus | 1.2 | 2,720 |
| Product | [Mpa] | | |
| Characteristics | | | |

### Example 1

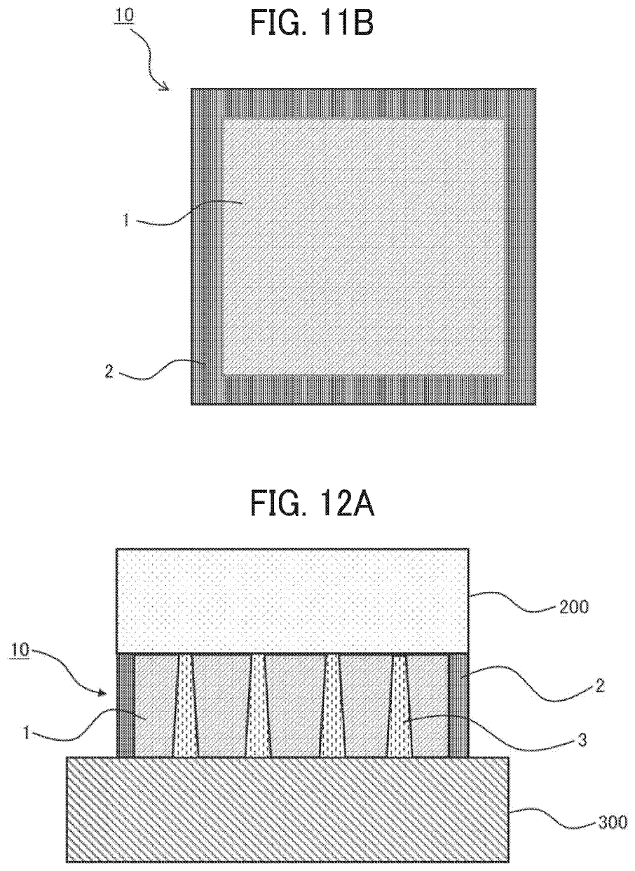

In Example 1, a layered adhesive structure as illustrated in FIGS. 11A and 11B was manufactured. For evaluation of adhesive strength, the adhesive structure was a bonded sample in which a printed wiring board (PWB) substrate 300 and a silicon substrate 200 are adhered to each other with the adhesive structure 10. The low elastic portion 2 and the adhesive portion 1 in the adhesive structure 10 were formed by inkjet printing. As an inkjet device, an inkjet device (Stage JET, manufactured by Tritek Co., Ltd.) equipped with MH5420 (manufactured by Ricoh Co., Ltd.) as an inkjet head was used. The specific method was as follows.

### <Manufacturing of Bonded Sample Using Layered Adhesive Structure>

### —Preparation of Substrate—

A square printed wiring board (PWB) substrate with a length of 10 mm, a width of 10 mm, and a thickness of 1.6 mm (a substrate obtained by coating and curing a solder resist on the surface of a glass epoxy RF-4) was prepared. As the solder resist, PSR-4000 SP19A/CA-40 SP19A (manufactured by TAIYO HOLDING CO., LTD.) was used. The linear thermal expansion coefficient of the PWB substrate was 15.7 ppm/K, and the linear thermal expansion coefficient of silicon was 3.34 ppm/K.

### —Design—

As illustrated in FIG. 11B, a square adhesive structure formation region with four sides of 5 mm was designed at the center of the PWB substrate in the plane direction. In that design, the center of the adhesive structure formation region and the center of the PWB substrate coincided with each other. A low elastic portion formation region was designed to have a width of 0.35 mm around a square adhesive structure formation region with four sides of 4.3 mm.

—Formation of Low Elastic Portion—As the low elastic portion forming ink, the [low elastic portion forming ink B-1] in Table 3-2 using the materials in Table 2 was used to be inkjet-printed, based on the design, in the low elastic portion formation region on the PWB substrate. Furthermore, a low elastic portion with an average thickness of 15 μm and a width of 0.5 mm was formed by subjecting the discharged droplets to subject pre-photocuring with a UV LED (365 nm) using Honle LED Cube 100 (manufactured by Honle UV Technology).

### —Formation of Adhesive Portion—

Next, as the adhesive portion forming ink, the [adhesive portion forming ink A-1] in Table 3-1 using the materials in Table 2 was used to be inkjet-printed, based on the design, in the adhesive portion formation region that is a square with four sides of 4.3 mm inside the low elastic portion formed on the PWB substrate, to form an adhesive portion. At this time, the amount of droplets of the [adhesive portion forming ink A-1] was controlled so that the average thickness was 15 μm. As a result, the layered adhesive structure 10 including the adhesive portion 1 and the low elastic portion 2, illustrated in FIGS. 11A and 11B was formed on the PWB substrate 300.

Next, the square silicon substrate 200 with a length of 5 mm, a width of 5 mm, and a thickness of 0.4 mm was bonded onto the opposite surface of the adhesive structure 10 to the surface of the adhesive structure 10 in contact with the PWB substrate 300. Then, the resulting structure was heated at 100° C. for 2 hours, and further subjected to heat curing treatment at 200° C. for 1 hour to manufacture a sample using the adhesive structure of Example 1, illustrated in FIGS. 11A and 11B, in which the PWB substrate 300 and the silicon substrate 200 were bonded together with the adhesive structure 10.

The average thickness of the low elastic portion and the adhesive portion was an average of thicknesses measured at any three points of the low elastic portion or the adhesive portion with a stylus meter (Alpha-Step D-500, manufactured by KLA-Tencore). It is the average value of three places.

### Example 2

A bonded sample using a layered adhesive structure of Example 2 was manufactured in the same manner as in Example 1, except that the planar pattern of the low elastic portion was changed to the pattern illustrated in FIG. 4E as compared to Example 1. In the pattern illustrated in FIG. 4E, the pattern of the adhesive portion illustrated in FIG. 11B was divided into 9 sections in the plane direction by low elastic portions with a width of 0.15 mm that are continuous in the thickness direction in the adhesive structure.

### Example 3

A bonded sample using a layered adhesive structure of Example 3 was manufactured in the same manner as in Example 1, except that the [low elastic portion forming ink B-1] was changed to the [low elastic portion forming ink B-2] to be discharged as compared to Example 1.

The [low elastic portion forming ink B-2] was not subjected to photocuring treatment because the [low elastic portion forming ink B-2] was a thermosetting ink.

### Example 4

A bonded sample using a layered adhesive structure of Example 4 was manufactured in the same manner as in Example 3, except that the [adhesive portion forming ink A-1] was changed to the [adhesive portion forming ink A-2] as compared to Example 3.

### Example 5

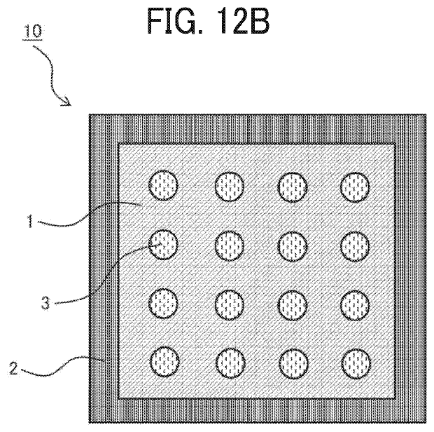

In Example 5, a layered adhesive structure as illustrated in FIGS. 12A and 12B was manufactured. For evaluation of adhesive strength, the layered adhesive structure was a bonded sample in which the PWB substrate 300 and the silicon substrate 200 are adhered to each other with the adhesive structure 10. The PWB substrate, solder resist, and silicon substrate as used were the same as those in Example 1. The low elastic portion 2 and the adhesive portion 1 in the adhesive structure 10 were formed by inkjet printing. The inkjet device as used was the same as in Example 1. The specific method was as follows.

### <Manufacturing of Bonded Sample Using Layered Adhesive Structure>—Design—

As illustrated in FIG. 12B, a square adhesive structure formation region with four sides of 5 mm was designed at the center of the PWB substrate in the plane direction. In that design, the center of the adhesive structure formation region and the center of the PWB substrate coincided with each other. A low elastic portion formation region was designed to have a width of 0.2 mm around the square adhesive structure formation region. Furthermore, in Example 5, a thermally conductive portion formation region was designed in the adhesive structure formation region. Specifically, 4 in length×4 in width, which is 16 in total, perfect circular thermally conductive portion formation regions each having a radius of 2 mm were designed so that the distance between the centers of adjacent thermally conductive portion formation regions was 10 mm. In addition, the shortest distance between the low elastic portion formation region and the outer circumferences of the thermally conductive portion formation regions was designed to be 8.8 mm.

### —Formation of Low Elastic Portion—

As the low elastic portion forming ink, the [low elastic portion forming ink B-1] in Table 3-2 using the materials in Table 2 was used to be inkjet-printed, based on the design, in the low elastic portion formation region on the PWB substrate. Furthermore, a low elastic portion with an average thickness of 15 μm and a width of 0.2 mm was formed by subjecting the discharged droplets to pre-photocuring with a UV LED (365 nm) using Honle LED Cube 100 (manufactured by Honle UV Technology).

### —Formation of Adhesive Portion—

Next, as the adhesive portion forming ink, the [adhesive portion forming ink A-3] in Table 3-1 using the materials in Table 2 was used to be inkjet-printed, based on the design, in a region excluding the thermally conductive portion formation region (the adhesive portion formation region) inside the low elastic portion formed on the PWB substrate. Furthermore, the discharged droplets was subject to pre-photocuring with a UV LED (365 nm) using Honle LED Cube 100 (manufactured by Honle UV Technology). At this time, the amount of droplets of the [adhesive portion forming ink A-3] was controlled so that the average thickness was 15 μm.

### —Formation of Thermally Conductive Portion—

Furthermore, as the thermally conductive portion forming ink, Ag nanoparticle ink (SMART INK Smart Jet 1 (S-CS01520), manufactured by GenesInk) was used to be inkjet-printed, based on the design, in the thermally conductive portion formation region. The solvent of the discharged Ag nanoparticle ink was removed from the thermally conductive portion forming ink by heating the PWB substrate at 100° C. at the time of inkjet printing. As a result, the layered adhesive structure 10 including the adhesive portion 1, the low elastic portion 2, and the thermally conductive portion 3, illustrated in FIGS. 12A and 12B was formed on the PWB substrate 300.

Next, the square silicon substrate 200 with a length of 5 mm, a width of 5 mm, and a thickness of 0.4 mm was bonded onto the opposite surface of the adhesive structure 10 to the surface of the adhesive structure 10 in contact with the PWB substrate 300. Then, the resulting structure was heated at 100° C. for 2 hours, and further subjected to heat curing treatment at 200° C. for 1 hour to manufacture a sample using the adhesive structure 10 including the thermally conductive portion 3 of Example 5, illustrated in FIGS. 12A and 12B, in which the PWB substrate 300 and the silicon substrate 200 were bonded together with the adhesive structure 10.

### Comparative Example 1

A bonded sample of a layered adhesive structure of Comparative Example 1 was manufactured in the same manner as in Example 1, except that the design was changed as follows and the low elastic portion was not formed as compared to Example 1.

### —Design—

A square adhesive structure formation region with four sides of 5 mm was designed at the center of the PWB substrate in the plane direction. In that design, the center of the adhesive structure formation region and the center of the PWB substrate coincided with each other.

### Comparative Example 2

A bonded sample using a layered adhesive structure of Comparative Example 2 in which the low elastic portion was not formed was manufactured in the same manner as in Comparative Example 1, except that the [adhesive portion forming ink A-1] was changed to the [adhesive portion forming ink A-2] as compared to Comparative Example 1.

### Comparative Example 3

A bonded sample using a layered adhesive structure of Comparative Example 3 in which the low elastic portion was not formed was manufactured in the same manner as in Comparative Example 1, except that the [adhesive portion forming ink A-1] was changed to the [low elastic portion forming ink B-1] as compared to Comparative Example 1.

### Comparative Example 4

A bonded sample using a layered adhesive structure of Comparative Example 4 in which the low elastic portion was not formed was manufactured in the same manner as in Comparative Example 1, except that the [adhesive portion forming ink A-1] was changed to an ink in which the [adhesive portion forming ink A-2] and the [low elastic portion forming ink B-2] were mixed (A-2:B-2=74:26, mass ratio) as compared to Comparative Example 1.

### <Measurement of Die Shear Strength>

As evaluation of adhesive strength of the samples of Examples 1 to 5 and Comparative Examples 1 to 4 in a heated state, evaluation of shear strength (evaluation of die shear strength) at 260° C. was performed by the following method. The samples of Examples 1 to 5 and Comparative Examples 1 to 4 were evaluated for shear adhesive strength (die shear strength) in a state of being heated at 260° C. were evaluated with a bond tester (Dage 4000, Nordson Corporation). The measurement conditions conformed to Japan Electronics and Information Technology Industries Association (JEITA) standard ED-4703 K-111. The results are presented in Table 4 below.

TABLE 4

| | | | | | | Low Elastic | |
|---|---|---|---|---|---|---|---|
| | | | | | Elastic | Portion | |
| | | | | | Modulus | Content | |
| | Adhesive Portion | | Low Elastic Portion | | Ratio | Ratio | |
| | Forming Ink | | Forming Ink | | Low Elastic | Low Elastic | |
| | | Indentation | | Indentation | Portion/ | Portion/ | Evaluation |
| Example/ | | Elastic | | Elastic | Adhesive | Adhesive | Die Shear |
| Comparative | | Modulus | | Modulus | Portion | Structure | Strength |
| Example | Type | [Mpa] | Type | [Mpa] | [%] | [Volume (%)] | [N] |
| Example 1 | A-1 | 4,666 | B-1 | 1.2 | 0.03 | 26 | 88.4 |
| Example 2 | A-1 | 4,666 | B-1 | 1.2 | 0.03 | 41 | 117.2 |
| Example 3 | A-1 | 4,666 | B-2 | 2,702 | 57.91 | 26 | 90.1 |
| Example 4 | A-2 | 7,200 | B-2 | 2,702 | 37.53 | 26 | 16.5 |
| Example 5 | A-3 | 3,150 | B-1 | 1.2 | 0.04 | 15 | 12.3 |
| Comparative | A-1 | 4,666 | No | — | — | 0 | 83.9 |
| Example 1 | | | | | | | |
| Comparative | A-2 | 7,200 | No | — | — | 0 | 6.0 or less |
| Example 2 | | | | | | | |
| Comparative | B-1 | 1.2 | No | — | — | 0 | 6.0 or less |
| Example 3 | | | | | | | |
| Comparative | A-2:B-2 | 6,000 | No | — | — | 0 | 6.0 or less |
| Example 4 | (74:26) | | | | | | |

From the results in Table 4, the adhesive strengths of Examples 1 to 5 were found to have good die shear strength. Moreover, the die shear strengths were found to be high compared to the comparative examples. In Table 4, the ratio of the elastic modulus of the low elastic portion to the elastic modulus of the adhesive portion (elastic modulus ratio) was calculated from the following Equation (1), and the volume ratio of the low elastic portion to the adhesive structure (low elastic portion content ratio) was calculated from the following Equation (2).

$$Equation ( 1 )$$

$$Elastic modulus ratio ( \% ) = Elastic modulus of low elastic portion / Elastic modulus of adhesive portion \times 100$$

$$Equation ( 2 )$$

$$Low elastic portion content ratio ( vol \% ) = Volume of low elastic portion / Volume of entire adhesive structure \times 100$$

### Test Example 1: Evaluation of Characteristics of Thermally Conductive Portion

A glass substrate with a length of 40 mm, a width of 40 mm, and a thickness of 1 mm was prepared, and designed as follows to manufacture a sample for evaluating the characteristics of the thermally conductive portion.

### —Design—

A square thermally conductive portion formation region with four sides of 15 mm was designed at the center of the glass substrate in the plane direction. In that design, the center of the thermally conductive portion formation region and the center of the glass substrate coincided with each other.

### —Formation of Thermally Conductive Portion—

As the thermally conductive portion forming ink, Ag nanoparticle ink (SMART INK Smart Jet 1 (S-CS01520), manufactured by GenesInk) was used to be inkjet-printed, based on the design, in the thermally conductive portion formation region on the glass substrate. The solvent of the discharged Ag nanoparticle ink was removed from the thermally conductive portion forming ink by heating the glass substrate at 100° C. at the time of coating. After that, the resulting ink was heated at 100° C. for 2 hours and further subjected to heat curing treatment at 200° C. for 1 hour. As a result, a square thermally conductive portion with four sides of 15 mm and an average thickness of 15 μm was formed on the glass substrate.

### <Measurement of Volume Resistivity>

The resistance value of the manufactured sample was measured with a 4-terminal resistance measuring machine (Loresta-GP, manufactured by Mitsubishi Chemical Analytech Co., Ltd.). As a result, the volume resistivity of the sample was 1.0×10{1}−5{2} Ω·cm.

### <SEM Observation>

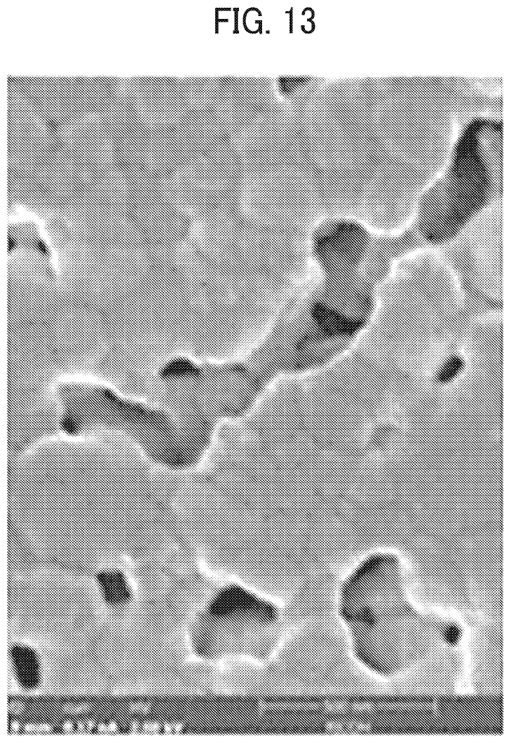

The manufactured sample was observed using a scanning electron microscope (SEM) (NVision 40 (Carl ZEISS), manufactured by SII). The result of the SEM observation is presented in FIG. 13. From FIG. 13, it was found that the nanoparticles were bonded to each other, that is, sintered.

### <Measurement of Film Thickness and Surface Roughness>

The thickness and surface roughness of the manufactured sample were measured using a stylus profiler (Alpha-Step D-500, manufactured by KLA-Tencore). As a result, the average thickness was 15 μm as described above, and the surface roughness was 30 nm or less.

Examples of aspects of the present embodiment include, but are not limited to, the following.

<1> An adhesive structure including: an adhesive portion to adhere to a contact object; and a low elastic portion having an elastic modulus lower than an elastic modulus of the adhesive portion, in which at least one of the adhesive portion and the low elastic portion has a patterned shape.
<2> The adhesive structure according to <1>, in which the adhesive structure is a layered adhesive structure.
<3> The adhesive structure according to any one of <1> to <2>, wherein shapes and sizes of a part of the adhesive portion and a part of the low elastic portion which are exposed on one surface are different from shapes and sizes of another part of the adhesive portion and another part of the low elastic portion which are exposed on another surface.
<4> The adhesive structure according to any one of <1> to <3>, wherein at least one of the adhesive portion and the low elastic portion has a size of 10 μm or more in a plane direction in the adhesive structure.
<5> The adhesive structure according to any one of <1> to <4>, wherein a volume ratio of the low elastic portion to the adhesive structure is from 5% to 90%.
<6> The adhesive structure according to any one of <1> to <5>, wherein the elastic modulus of the low elastic portion is 70% or less of the elastic modulus of the adhesive portion.
<7> The adhesive structure according to any one of <1> to <6>, wherein the elastic modulus of the low elastic portion is 3,000 MPa or less.
<8> The adhesive structure according to any one of <1> to <7>, including a thermally conductive portion continuous in a thickness direction.
<9> The adhesive structure according to any one of <1> to <8>, wherein at least one of the adhesive portion and the low elastic portion contains a photocurable resin.
<10> An adhesive layer for transfer, including a temporary support body and the adhesive structure according to any one of <1> to <9> being a layered adhesive structure on the temporary support body.
<11> An electronic component including the adhesive structure according to any one of <1> to <9>.
<12> The electronic component according to <11>, further including a first component and a second component fixed to the first component by the adhesive structure.
<13> The electronic component according to <12>, wherein a difference in linear thermal expansion coefficient between the first component and the second component is from 0 ppm/K to 20 ppm/K.
<14> The electronic component according to any one of <12> to <13>, wherein the low elastic portion in the adhesive structure prevents deformation caused by a difference in linear thermal expansion coefficient between the first component and the second component.
<15> The electronic component according to any one of <12> to <14>, wherein the first component is a heat-generating component or a cooling component, and the second component is a substrate.
<16> The electronic component according to any one of <12> to <15>, wherein the first component is a semiconductor.
<17> The electronic component according to any one of <11> to <16>, wherein the adhesive structure is at least one of a die bonding layer, a heat dissipation layer, and a resist.
<18> A method for manufacturing an adhesive structure, including:
discharging an adhesive portion forming ink for forming an adhesive portion to adhere to a contact object, from a nozzle, to pattern the adhesive portion; and
discharging a low elastic portion forming ink for forming a low elastic portion having an elastic modulus lower than an elastic modulus of the adhesive portion, from a nozzle, to pattern the low elastic portion.
   <19> The method for manufacturing an adhesive structure according to <18>, further including discharging a thermally conductive portion forming ink for forming a thermally conductive portion, from a nozzle, to form the thermally conductive portion continuous in a thickness direction of the adhesive structure.
   <20> The method for manufacturing an adhesive structure according to <19>, wherein the thermally conductive portion forming ink includes metal nanoparticles, and the method further includes sintering the metal nanoparticles after the discharging of the thermally conductive portion forming ink.
   <21> A method for manufacturing an electronic component, including fixing a component by using the adhesive structure according to any one of <1> to <9>.
   <22> The method for manufacturing an electronic component according to <21>, wherein the adhesive structure is a resist, and
the method further includes:
discharging an adhesive portion forming ink for forming an adhesive portion to adhere to a contact object, from a nozzle onto a substrate at a position corresponding to a first region that is an edge of a resulting resist pattern, to dispose the adhesive portion and to form a first resist layer;
discharging a low elastic portion forming ink for forming a low elastic portion having an elastic modulus lower than an elastic modulus of the adhesive portion, from a nozzle onto the substrate at a position corresponding to a second region that is different from the first region, to pattern and dispose the low elastic portion and to form a second resist layer; and
curing the first resist layer and the second resist layer to form resist patterns,
wherein the discharging of the adhesive portion forming ink and the discharging of the low elastic portion forming ink include
simultaneously disposing the adhesive portion forming ink and the low elastic portion forming ink on the substrate, and
forming a resist pattern in which a portion corresponding to the first region of the resist pattern formed by the adhesive portion forming ink and a portion corresponding to the second region of the resist pattern formed by the low elastic portion forming ink are continuous.

According to the adhesive structure according to any one of <1> to <9>, the adhesive layer for transfer according to <10>, the electronic component according to any one of <11> and <17>, the method for manufacturing an adhesive structure according to any one of <18> to <20>, and the method for manufacturing an electronic component according to any one of <21> to <22>, it is possible to solve various conventional problems and achieve the object of the present embodiment.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

This patent application is based on and claims priority to Japanese Patent Application Nos. 2022-044905 and 2022-190614, filed on Mar. 22, 2022 and Nov. 29, 2022, respectively, in the Japan Patent Office, the entire disclosure of each of which is hereby incorporated by reference herein.

### REFERENCE SIGNS LIST

1 Adhesive portion
2 Low elastic portion
3 Thermally conductive portion
4 Wire bonding contact portion
10 Adhesive layer
20 Substrate
30 Heat-generating component
30-1 Heat-generating component
30-2 Heat-generating component
40 Cooling component
50 Intermediate layer
60 Wiring portion
100 Conventional adhesive layer
101 Conventional adhesive portion
102 Conventional low elastic portion
200 Silicon substrate
300 Printed wiring board (PWB) substrate
501 Electrode
502 Electrode

1: An adhesive structure, comprising:
an adhesive portion to adhere to a contact object; and
a low elastic portion having an elastic modulus lower than an elastic modulus of the adhesive portion,
wherein at least one of the adhesive portion and the low elastic portion has a patterned shape.

2: The adhesive structure according to claim 1, wherein:
the adhesive structure is a layered adhesive structure.

3: The adhesive structure according to claim 1, wherein:
shapes and sizes of a part of the adhesive portion and a part of the low elastic portion which are exposed on one surface are different from shapes and sizes of another part of the adhesive portion and another part of the low elastic portion which are exposed on another surface.

4: The adhesive structure according to claim 1, wherein:
at least one of the adhesive portion and the low elastic portion has a size of 10 μm or more in a plane direction in the adhesive structure.

5: The adhesive structure according to claim 1, wherein:
a volume ratio of the low elastic portion to the adhesive structure is from 5% to 90%.

6: The adhesive structure according to claim 1, wherein:
the elastic modulus of the low elastic portion is 70% or less of the elastic modulus of the adhesive portion.

7: The adhesive structure according to claim 1, wherein:
the elastic modulus of the low elastic portion is 3,000 MPa or less.

8: The adhesive structure according to claim 1, further comprising:
a thermally conductive portion continuous in a thickness direction.

9: The adhesive structure according to claim 1, wherein:
at least one of the adhesive portion and the low elastic portion contains a photocurable resin.

10: An adhesive layer for transfer, comprising:
a temporary support body; and
the adhesive structure according to claim 1 being a layered adhesive structure on the temporary support body.

11: An electronic component comprising the adhesive structure according to claim 1.

12: The electronic component according to claim 11, further comprising:
a first component; and
a second component fixed to the first component by the adhesive structure.

13: The electronic component according to claim 12, wherein:
a difference in linear thermal expansion coefficient between the first component and the second component is from 0 ppm/K to 20 ppm/K.

14: The electronic component according to claim 12, wherein:
the first component is a heat-generating component or a cooling component, and the second component is a substrate.

15: The electronic component according to claim 12, wherein:
the first component is a semiconductor.

16: A method for manufacturing an adhesive structure, the method comprising:
discharging an adhesive portion forming ink for forming an adhesive portion to adhere to a contact object, from a nozzle, to pattern the adhesive portion; and
discharging a low elastic portion forming ink for forming a low elastic portion having an elastic modulus lower than an elastic modulus of the adhesive portion, from a nozzle, to pattern the low elastic portion.

17: The method for manufacturing an adhesive structure according to claim 16, further comprising:
discharging a thermally conductive portion forming ink for forming a thermally conductive portion, from a nozzle, to form the thermally conductive portion continuous in a thickness direction of the adhesive structure.

18: The method for manufacturing an adhesive structure according to claim 17, wherein:
the thermally conductive portion forming ink includes metal nanoparticles, and
the method further comprises sintering the metal nanoparticles after the discharging of the thermally conductive portion forming ink.

19: A method for manufacturing an electronic component, the method comprising:
fixing a component by using the adhesive structure according to claim 1.

20: The method for manufacturing an electronic component according to claim 19, wherein:
the adhesive structure is a resist, and
the method further comprises:
discharging an adhesive portion forming ink for forming an adhesive portion to adhere to a contact object, from a nozzle onto a substrate at a position corresponding to a first region that is an edge of a resulting resist pattern, to dispose the adhesive portion thereby to form a first resist layer;
discharging a low elastic portion forming ink for forming a low elastic portion having an elastic modulus lower than an elastic modulus of the adhesive portion, from a nozzle onto the substrate at a position corresponding to a second region that is different from the first region, to pattern and dispose the low elastic portion thereby to form a second resist layer; and
curing the first resist layer and the second resist layer to form resist patterns,
wherein the discharging of the adhesive portion forming ink and the discharging of the low elastic portion forming ink include;
simultaneously disposing the adhesive portion forming ink and the low elastic portion forming ink on the substrate, and
forming a resist pattern in which a portion corresponding to the first region of the resist pattern formed by the adhesive portion forming ink and a portion corresponding to the second region of the resist pattern formed by the low elastic portion forming ink are continuous.
